(19) United States
(12) Patent Application Publication
(10) Pub. No.: US 2025/0340695 A1
(43) Pub. Date: Nov. 6, 2025

(54) COMPOSITION, TRANSFER FILM, METHOD FOR MANUFACTURING LAMINATE, LAMINATE, AND CURED FILM

(71) Applicant: FUJIFILM CORPORATION, Tokyo (JP)

(72) Inventor: Keigo Yamaguchi, Kanagawa (JP)

(21) Appl. No.: 19/267,148

(22) Filed: Jul. 11, 2025

Related U.S. Application Data
(63) Continuation of application No. PCT/JP2024/004730, filed on Feb. 13, 2024.

(30) Foreign Application Priority Data
Feb. 28, 2023 (JP) 2023-029751

(51) Int. Cl. C08G 59/62; C08K 3/013; G03F 7/038

(52) U.S. Cl. CPC C08G 59/621; C08K 3/013; G03F 7/038

(57) ABSTRACT

An object of the present invention is to provide a composition with which a film having excellent dielectric characteristics and excellent migration resistance can be formed, a transfer film, a method for manufacturing a laminate, a laminate, and a cured film. The composition of the present invention contains a resin and a filler X surface-modified with a surface modifier, in which a content of the filler X is 50.0% by mass or more with respect to the total solid content of the composition, an average particle diameter of the filler X is 300 nm or less, and a content of the surface modifier is 3.0% by mass or less with respect to the total mass of the filler X.

### CROSS-REFERENCE TO RELATED APPLICATIONS

This application is a Continuation of PCT International Application No. PCT/JP2024/004730 filed on Feb. 13, 2024, which claims priority under 35 U.S.C. § 119(a) to Japanese Patent Application No. 2023-029751 filed on Feb. 28, 2023. The above applications are hereby expressly incorporated by reference, in their entirety, into the present application.

### BACKGROUND OF THE INVENTION

### 1. Field of the Invention

The present invention relates to a composition, a transfer film, a method for manufacturing a laminate, a laminate, a cured film.

In a display device provided with a touch panel such as a capacitive input device (such as an organic electroluminescence (EL) display device and a liquid crystal display device), a conductive pattern such as an electrode pattern corresponding to a sensor in a visual recognition portion and a wiring line for a peripheral wiring portion and a lead-out wiring portion is provided inside the touch panel. In addition, in a multilayer printed wiring board, an insulating film is provided between respective layers.

As a composition forming the insulating film, for example, JP2007-254709A discloses an epoxy resin composition having a predetermined configuration.

### SUMMARY OF THE INVENTION

The present inventors have found that it is difficult to achieve both dielectric characteristics and migration resistance of a film to be formed of a composition having the configuration as disclosed in JP2007-254709A.

An object of the present invention is to provide a composition with which a film having excellent dielectric characteristics and excellent migration resistance can be formed.

Another object of the present invention is to provide a transfer film, a method for manufacturing a laminate, a laminate, and a cured film, which are related to the above-described composition.

As a result of intensive studies to achieve the above-described objects, the present inventors have found that the above-described objects can be achieved by the following configurations, and have completed the present invention.

[1]

A composition comprising:
a resin; and
a filler X surface-modified with a surface modifier,
in which a content of the filler X is 50.0% by mass or more with respect to a total solid content of the composition,
an average particle diameter of the filler X is 300 nm or less, and
a content of the surface modifier is 3.0% by mass or less with respect to a total mass of the filler X.

[2]

The composition according to [1],
in which the filler X includes at least one selected from the group consisting of silicon dioxide, boron nitride, barium sulfate, and silicate.

[3]

The composition according to [1] or [2],
in which the average particle diameter of the filler X is 150 nm or less.

[4]

The composition according to any one of [1] to [3],
in which the content of the filler X is 90.0% by mass or less with respect to the total solid content of the composition.

[5]

The composition according to any one of [1] to [4],
in which the content of the surface modifier is 2.5% by mass or less with respect to the total mass of the filler X.

[6]

The composition according to any one of [1] to [5],
in which the resin includes at least one selected from the group consisting of a phenol resin, an epoxy resin, a polyphenylene ether resin, a silicone resin, a benzocyclobutene resin, a fluorene resin, an acrylic resin, a methacrylic resin, a liquid crystal polymer, a polyethersulfone, a polyarylate, a polyether imide, a polybenzimidazole, a polyphenylsulfone, a polycarbonate, an acrylonitrile-butadiene-styrene resin, and a polyphenylene sulfide.

[7]

The composition according to any one of [1] to [6],
in which the resin includes at least one selected from the group consisting of a phenol resin and an epoxy resin.

[8]

The composition according to any one of [1] to [7],
in which the composition contains no sodium ion, or
in a case of containing a sodium ion, a content of the sodium ion is 50 ppm by mass or less with respect to the total solid content of the composition.

[9]

The composition according to any one of [1] to [8],
in which the composition contains no chloride ion, or
in a case of containing a chloride ion, a content of the chloride ion is 50 ppm by mass or less with respect to the total solid content of the composition.

[10]

The composition according to any one of [1] to [9],
in which the composition satisfies at least one of containing the resin having an ethylenically unsaturated group or further containing a polymerizable compound having an ethylenically unsaturated group.

[11]

The composition according to [10], further comprising:
a photopolymerization initiator.

[12]

A transfer film comprising:
a temporary support; and
a composition layer formed of the composition according to any one of [1] to [11].

[13]

A method for manufacturing a laminate, comprising:
a step of forming a composition layer on a base material using the composition according to any one of [1] to [11];
a step of forming a pattern having a via on the composition layer; and
a step of heating or exposing the pattern.

[14]

A laminate manufactured by the method for manufacturing a laminate according to [13].

[15]

A cured film obtained by curing the composition according to [7].

According to the present invention, it is possible to provide a composition with which a film having excellent dielectric characteristics and excellent migration resistance can be formed.

In addition, it is also possible to provide a transfer film, a method for manufacturing a laminate, a laminate, and a cured film, which are related to the above-described composition.

### BRIEF DESCRIPTION OF THE DRAWINGS

FIG. 1 is a diagram (nomograph) describing a boiling point measuring method of a compound Y.

FIG. 2 is a schematic view showing an example of a layer configuration of a transfer film.

### DESCRIPTION OF THE PREFERRED EMBODIMENTS

Hereinafter, the present invention will be described in detail.

In the present specification, a numerical range expressed using “to” means a range that includes the proceeding and succeeding numerical values of “to” as a lower limit value and an upper limit value, respectively.

In addition, regarding numerical ranges that are described stepwise in the present specification, an upper limit value or a lower limit value described in a numerical range may be replaced with an upper limit value or a lower limit value of another stepwise numerical range. In addition, regarding the numerical range described in the present specification, an upper limit value or a lower limit value described in a numerical value may be replaced with a value described in Examples.

In addition, a term “step” in the present specification includes not only an independent step but also a step that cannot be clearly distinguished from other steps, as long as the intended purpose of the step is achieved.

In the present specification, a temperature condition may be set to 25° C. unless otherwise specified. For example, unless otherwise specified, a temperature at which each of the above-described steps is performed may be 25° C.

In the present specification, “transparent” means that an average transmittance of visible light having a wavelength of 400 nm to 700 nm is 80% or more, preferably 90% or more.

In addition, the average transmittance of visible light is a value measured by using a spectrophotometer, and for example, can be measured by using a spectrophotometer U-3310 manufactured by Hitachi, Ltd.

In the present specification, “actinic ray” or “radiation” means a bright line spectrum of a mercury lamp such as g-rays, h-rays and i-rays, or far ultraviolet rays typified by an excimer laser, extreme ultraviolet rays (EUV light), X-rays, electron beams (EB). “Light” means actinic ray or radiation.

Unless otherwise specified, “exposure” in the present specification encompasses not only exposure by a mercury lamp, far ultraviolet rays typified by an excimer laser, extreme ultraviolet rays, X-rays, EUV light, or the like, but also exposure of drawing by corpuscular beams such as electron beams and ion beams.

In the present specification, a refractive index is a value measured with an ellipsometer at a wavelength of 550 nm unless otherwise specified.

In the present specification, unless otherwise specified, a molecular weight in a case of a molecular weight distribution is a weight-average molecular weight. In the present specification, a weight-average molecular weight (Mw) and a number-average molecular weight (Mn) are values in terms of polystyrene by gel permeation chromatography (GPC).

In the present specification, “(meth)acrylic acid” is a concept including both acrylic acid and methacrylic acid; “(meth)acryloyl group” is a concept including both an acryloyl group and a methacryloyl group; “(meth)acrylate” is a concept including both acrylate and methacrylate; and “(meth)acrylic resin” is a concept including both an acrylic resin and a methacrylic resin.

In the present specification, “water-soluble” means that the solubility in 100 g of water with a pH of 7.0 at a liquid temperature of 22° C. is 0.1 g or more.

“Solid content” of a composition means a component forming a composition layer formed of the composition, and in a case where the composition contains a solvent (for example, organic solvent, water, and the like), the solid content means all components excluding the solvent. In addition, in a case where the components are components which form a composition layer, the components are considered to be solid contents even in a case where the components are liquid components.

In the present specification, unless otherwise specified, a thickness of a layer is an average thickness measured using a scanning electron microscope (SEM) for a thickness of 0.5 μm or more, and is an average thickness measured using a transmission electron microscope (TEM) for a thickness of less than 0.5 μm. The above-described average thickness is an average thickness obtained by producing a section to be measured using an ultramicrotome, measuring thicknesses of any five points, and arithmetically averaging the values.

### [Composition]

The composition according to the embodiment of the present invention contains a resin and a filler X surface-modified with a surface modifier, in which a content of the filler X is 50.0% by mass or more with respect to the total solid content of the composition, an average particle diameter of the filler X is 300 nm or less, and a content of the surface modifier is 3.0% by mass or less with respect to the total mass of the filler X.

Although the detailed action mechanism of the composition according to the embodiment of the present invention is not clear, the present inventors have presumed as follows. Since the composition according to the embodiment of the present invention contains the characteristic filler X, it is presumed that dielectric characteristics and migration resistance of a film to be obtained by using the composition according to the embodiment of the present invention are excellent. In addition, since the composition according to the embodiment of the present invention contains the resin, the above-described film can be formed. The above-described film to be formed may have a patterned shape.

Hereinafter, the fact that at least one of the effect of further improving the dielectric characteristics of the film to be formed or the effect of further improving the migration resistance of the film to be formed is obtained is also referred to as “effect of the present invention is more excellent”.

Hereinafter, various components which can be contained in the composition according to the embodiment of the present invention will be described in detail.

### [Resin]

The composition contains a resin.

The resin is different from various components described later.

The resin may be a thermoplastic resin or a thermosetting resin.

The resin may have a polymerizable group. As the above-described polymerizable group, an ethylenically unsaturated group is preferable; a (meth)acryloyl group, a vinyl group, or a styryl group is more preferable; and a (meth)acryloyl group is still more preferable.

The resin may be any of an unmodified product or a modified product unless otherwise specified. For example, an epoxy resin is a resin having an epoxy group, and may further have a functional group other than the epoxy group or have a structure including the functional group.

Examples of the resin include known resins.

The resin preferably includes at least one selected from the group consisting of a phenol resin, an epoxy resin, a polyphenylene ether resin, a silicone resin, a benzocyclobutene resin, a fluorene resin, a (meth)acrylic resin, a liquid crystal polymer, a polyethersulfone, a polyarylate, a polyether imide, a polybenzimidazole, a polyphenylsulfone, a polycarbonate, an acrylonitrile-butadiene-styrene resin (ABS resin), and a polyphenylene sulfide; more preferably includes at least one selected from the group consisting of a phenol resin, an epoxy resin, a polyphenylene ether resin, a silicone resin, a benzocyclobutene resin, a fluorene resin, a (meth)acrylic resin, and a liquid crystal polymer; still more preferably includes at least one selected from the group consisting of a phenol resin, an epoxy resin, a polyphenylene ether resin, a silicone resin, a benzocyclobutene resin, a (meth)acrylic resin, and a liquid crystal polymer; and particularly preferably includes at least one selected from the group consisting of a phenol resin and an epoxy resin from the viewpoint of easily obtaining a cured film. The phenol resin is a resin having a phenolic hydroxyl group.

Examples of the phenol resin include a phenol novolac resin, a cresol novolac resin, a biphenyl aralkyl-type phenol resin, a naphthol aralkyl resin, and a naphthol novolac resin.

Examples of the phenol resin include AV LITE series manufactured by ASAHI YUKIZAI CORPORATION, such as TR4020G, TR4050G, TR4080G, TR5020G, TR5050G, TR6020G, TR6050G, and TR6080G; photoresist resin series manufactured by Sumitomo Bakelite Co., Ltd.; RESITOP series manufactured by Gun Ei Chemical Industry Co., Ltd.; PR-30-40P, PR-100L, PR-100H, PR-50, PR-55, PR-56-1, PR-56-2, PHENOLITE series manufactured by DIC Corporation, such as WR-101, WR-102, WR-103 and WR-104; photoresist resins Lignyte Inc., such as LF-100, LF-110, LF-120, LF-200, LF-400 and LF-500; MEHC-7851SS, MEHC-78004S, MEHC-7851-SS, MEHC-7851-S, MEHC-7851-M, MEHC-7851-H, MEHC-7800-4S, MEHC C-7800-SS, MEHC-7800-S, MEHC-7800-M, and MEHC-7800-H manufactured by MEIWA PLASTIC INDUSTRIES, LTD.; GPH-65, GPH-103, and MEHC-7841-4S manufactured by Nippon Kayaku Co., Ltd.; BisP-AP, B isP-MIBK, BisP-B, Bis-Z, BisP-CP, o,o′-BPF, BisP-IOTD, BisP-IBTD, BisP-DED, BisP-BA, Bis-C, Bis26X-A, BisOPP-A, BisOTBP-A, BisOCHP-A, BisOFP-A, BisOC-Z, BisOC-FL, BisOC-CP, BisOCHP-Z, methylenebisP-CR, TM-BPF, BisOC-F, Bis3M6B-IBTD, BisOC-IST, BisP-IST, BisP-PRM, BisP-LV, BisE, and BisP-TMC manufactured by Honshu Chemical Industry Co., Ltd.; and BisA, BisF, and BisP-M manufactured by MITSUI FINE CHEMICALS, INC.

Examples of the phenol resin also include those described in JP2021-157174A.

The epoxy resin is a resin having an epoxy group.

Examples of the epoxy resin include a bisphenol A-type epoxy resin, a bisphenol F-type epoxy resin, a bisphenol S-type epoxy resin, a bisphenol AF-type epoxy resin, a dicyclopentadiene-type epoxy resin, a trisphenol epoxy resin, a naphthol novolac epoxy resin, a phenol novolac-type epoxy resin, a tert-butyl-catechol-type epoxy resin, a naphthalene-type epoxy resin, a naphthol-type epoxy resin, an anthracene-type epoxy resin, a glycidylamine-type epoxy resin, a glycidyl ester-type epoxy resin, a cresol novolac-type epoxy resin, a biphenyl-type epoxy resin, a linear aliphatic epoxy resin, an epoxy resin having a butadiene structure, an alicyclic epoxy resin, a heterocyclic epoxy resin, an epoxy resin containing a spiro ring, a cyclohexanedimethanol epoxy resin, a naphthylene ether-type epoxy resin, and a trimethylol-type epoxy resin.

From the viewpoint of excellent flexibility and improved breaking strength of a cured layer to be obtained, it is also preferable that the epoxy resin includes an epoxy resin which is liquid at a temperature of 20° C. (hereinafter, also referred to as “liquid epoxy resin”) and an epoxy resin which is solid at a temperature of 20° C. (hereinafter, also referred to as “solid epoxy resin”).

As the liquid epoxy resin, a bisphenol A-type epoxy resin, a bisphenol F-type epoxy resin, a phenol novolac-type epoxy resin, or a naphthalene-type epoxy resin is preferable; and a bisphenol A-type epoxy resin, a bisphenol F-type epoxy resin, or a naphthalene-type epoxy resin is more preferable.

Examples of the liquid epoxy resin include HP4032, HP4032D, EXA4032SS, and HP4032SS (naphthalene-type epoxy resins) manufactured by DIC Corporation; jER828EL (bisphenol A-type epoxy resin), jER807 (bisphenol F-type epoxy resin), and jER152 (phenol novolac-type epoxy resin) manufactured by Mitsubishi Chemical Corporation; and ZX1059 (mixed product of bisphenol A-type epoxy resin and bisphenol F-type epoxy resin) manufactured by NIPPON STEEL Chemical & Material Co., Ltd.

As the liquid epoxy resin, HP4032SS or ZX1059 is preferable.

As the solid epoxy resin, a tetrafunctional naphthalene-type epoxy resin, a cresol novolac-type epoxy resin, a dicyclopentadiene-type epoxy resin, a trisphenol epoxy resin, a naphthol novolac epoxy resin, a biphenyl-type epoxy resin, or a naphthylene ether-type epoxy resin is preferable; a tetrafunctional naphthalene-type epoxy resin, a biphenyl-type epoxy resin, or a naphthylene ether-type epoxy resin is more preferable; and a biphenyl-type epoxy resin is still more preferable.

Examples of the solid epoxy resin include HP-4700 and HP-4710 (tetrafunctional naphthalene-type epoxy resins), N-690 (cresol novolac-type epoxy resin), N-695 (cresol novolac-type epoxy resin), HP7200, HP7200H, HP7200K-65I (dicyclopentadiene-type epoxy resins), EXA7311, EXA7311-G3, and HP6000 (naphthylene ether-type epoxy resins) manufactured by DIC Corporation; EPPN-502H (trisphenol epoxy resin), NC7000L (naphthol novolac epoxy resin), NC3000H, NC3000, NC3000L, and NC3100 (biphenyl-type epoxy resins) manufactured by Nippon Kayaku Co., Ltd.; ESN475 (naphthol novolac-type epoxy resin) and ESN485 (naphthol novolac-type epoxy resin) manufactured by NIPPON STEEL Chemical & Material Co., Ltd.; and YX4000H, YL6121 (biphenyl-type epoxy resins), and YX4000HK (bixylenol-type epoxy resin) manufactured by Mitsubishi Chemical Corporation.

As the solid epoxy resin, YX4000HK, NC3000L, or HP7200H is preferable.

The polyphenylene ether resin is a resin having a phenylene ether group.

The polyphenylene ether resin may have a linear structure or a branched structure, and preferably have a branched structure.

In the polyphenylene ether resin having a branched structure, it is preferable that an ether bond is directly bonded to at least three positions of an ipso-position, an ortho-position, and a para-position of a benzene ring in at least one benzene ring constituting the polyphenylene ether resin.

The polyphenylene ether resin having a branched structure is obtained, for example, by polymerization using two or more kinds of phenol compounds.

As the above-described phenol compound, a phenol compound having a hydrogen atom at an ortho-position and a para-position and having a polymerizable group, or a mixture of a phenol compound having a hydrogen atom at an ortho-position and a para-position and not having a polymerizable group and a phenol compound not having a hydrogen atom at an-ortho position, having a hydrogen atom at a para-position, and having a polymerizable group is preferable.

Examples of the phenol compound used for the synthesis of the polyphenylene ether resin include o-vinylphenol, m-vinylphenol, o-allylphenol, m-allylphenol, 3-vinyl-6-methylphenol, 3-vinyl-6-ethylphenol, 3-vinyl-5-methylphenol, 3-vinyl-5-ethylphenol, 3-allyl-6-methylphenol, 3-allyl-6-ethylphenol, 3-allyl-5-methylphenol, 3-allyl-5-ethylphenol, phenol, o-cresol, m-cresol, o-ethylphenol, m-ethylphenol, 2,3-xylenol, 2,5-xylenol, 3,5-xylenol, o-tert-butylphenol, m-tert-butylphenol, o-phenylphenol, m-phenylphenol, 2-dodecylphenol, 2-allyl-6-methylphenol, 2-allyl-6-ethylphenol, 2-allyl-6-phenylphenol, 2-allyl-6-styrylphenol, 2,6-divinylphenol, 2,6-diallylphenol, 2,6-diisopropenylphenol, 2,6-dibutenylphenol, 2,6-diisobutenylphenol, 2,6-diisopentenylphenol, 2-methyl-6-styrylphenol, 2-vinyl-6-methylphenol, 2-vinyl-6-ethylphenol, 2,6-dimethylphenol, 2,3,6-trimethylphenol, 2-methyl-6-ethylphenol, 2-ethyl-6-n-propylphenol, 2-methyl-6-n-butylphenol, 2-methyl-6-phenylphenol, 2,6-diphenylphenol, and 2,6-ditolylphenol.

Among these, 2,6-dimethylphenol or 2-allylphenol is preferable as the above-described phenol compound.

In addition, it is also preferable that the polyphenylene ether resin has a polymerizable group.

The above-described polymerizable group is preferably an ethylenically unsaturated group, and more preferably a vinylphenyl group or a (meth)acryloyl group.

In addition, in a case where the polyphenylene ether resin has a polymerizable group, the composition preferably contains a maleimide compound described later. The above-described maleimide compound reacts with the polyphenylene ether resin to obtain a modified polyphenylene ether.

Examples of the modified polyphenylene ether include a resin obtained by curing a resin composition described in WO2022/102756A.

Examples of the polyphenylene ether resin include poly(2,6-diethyl-1,4-phenylene) ether, poly(2-ethyl-6-n-propyl-1,4-phenylene) ether, poly(2,6-di-n-propyl-1,4-phenylene) ether, poly(2-methyl-6-n-butyl-1,4-phenylene) ether, poly(2-ethyl-6-isopropyl-1,4-phenylene) ether, poly(2-methyl-6-chloroethyl-1,4-phenylene) ether, poly(2-methyl-6-hydroxyethyl-1,4-phenylene) ether, and poly(2-methyl-6-chloroethyl-1,4-phenylene) ether.

Examples of the polyphenylene ether resin also include resins described in JP2022-157695A.

The silicone resin is a resin having an organosiloxane structure.

Examples of the silicone resin include a curable silicone resin, a silicone graft resin, and a modified silicone resin such as an alkyl-modified silicone resin; and a curable silicone resin is preferable.

Examples of the curable silicone resin include an addition reaction-type silicone resin, a condensation reaction-type silicone resin, and an ultraviolet ray or electron beam-curable silicone resin.

Examples of the addition reaction-type silicone resin include a resin obtained by reacting polydimethylsiloxane in which a vinyl group is introduced into a terminal or a side chain with hydrogen siloxane using a platinum catalyst for curing.

Examples of the condensation reaction-type silicone resin include a resin having a three-dimensional crosslinking structure, which is formed by a condensation reaction of polydimethylsiloxane having a hydroxyl group at a terminal and polydimethylsiloxane having a hydrogen atom at a terminal using an organotin catalyst.

Examples of the ultraviolet ray-curable silicone resin include a silicone resin which uses the same radical reaction as silicone rubber crosslinking, a silicone resin which is photocured by introducing an unsaturated group, a silicone resin which decomposes an onium salt with an ultraviolet ray or an electron beam to produce a strong acid and cleaves an epoxy group for crosslinking, and a silicone resin which is crosslinked by an addition reaction of thiol to vinylsiloxane. Specific examples thereof include acrylate-modified polydimethylsiloxane and glycidoxy-modified polydimethylsiloxane.

Examples of the silicone resin also include a dimethylsiloxane-methylvinylsiloxane copolymer capped at both molecular chain terminals with a trimethylsiloxy group, a dimethylsiloxane-diphenylsiloxane-methylvinylsiloxane copolymer capped at both molecular chain terminals with a trimethylsiloxy group, and a dimethylsiloxane-diphenylsiloxane copolymer capped at both molecular chain terminals with a dimethylvinylsiloxy group. The silicone resin preferably has an aromatic ring.

As the aromatic ring, an aromatic hydrocarbon ring is preferable, an aromatic hydrocarbon ring having 6 to 12 carbon atoms is more preferable, and a benzene ring is still more preferable.

As the silicone resin, a modified silicone resin obtained by reacting an organosilicon compound with a hydrosilylation agent is also preferable.

The organosilicon compound preferably further has a polymerizable group.

Examples of the above-described polymerizable group include the polymerizable groups included in the resin.

Examples of the organosilicon compound include a compound having a silyl group, and 1,4-bis(dimethylsilyl)benzene or trivinylphenylsilane is preferable.

Examples of the hydrosilylation agent include platinum-based catalysts such as carbon powder carrying a platinum metal, platinum black, second platinum chloride, platinum chloric acid, a reaction product of platinum chloric acid and monohydric alcohol, a complex of platinum chloric acid and olefins, and platinum bisacetoacetate; and platinum group metal-based catalysts such as a palladium-based catalyst and a rhodium-based catalyst.

A reaction temperature is preferably 100° C. to 200° C., and a reaction time is preferably 1 to 10 hours.

Examples of the silicone resin also include a resin obtained from an organosiloxane and a curable composition, which are described in JP2020-026502A.

The benzocyclobutene resin is a resin having a benzocyclobutene ring.

Examples of the benzocyclobutene resin include a divinylsiloxane-bisbenzocyclobutene resin (for example, CYCLOTENE resin manufactured by Dow Chemical Company).

The (meth)acrylic resin is a resin having a repeating unit derived from a compound selected from (meth)acrylic acid and a (meth)acrylic acid ester.

Examples of the repeating unit derived from a (meth)acrylic acid ester include a repeating unit derived from a (meth)acrylic acid alkyl ester.

The number of carbon atoms in the alkyl group constituting the (meth)acrylic acid alkyl ester (—COOR, an alkyl group in the R portion) is preferably 1 to 50, more preferably 1 to 10, and still more preferably 1 to 6. The above-described alkyl group may be linear, branched, or cyclic.

Examples of the (meth)acrylic acid alkyl ester include methyl (meth)acrylate.

The total content of the repeating units derived from (meth)acrylic acid and the (meth)acrylic acid ester is preferably 20% by mass or more, and more preferably 50% by mass or more with respect to all repeating units of the (meth)acrylic resin. The upper limit thereof is preferably 100% by mass or less, and more preferably 90% by mass or less.

The (meth)acrylic resin may have a repeating unit having an aromatic ring.

The repeating unit having an aromatic ring may be a repeating unit derived from a (meth)acrylic acid ester. In other words, the repeating unit having an aromatic ring may be a repeating unit derived from a (meth)acrylic acid ester having an aromatic ring group.

As the aromatic ring, an aromatic hydrocarbon ring is preferable, an aromatic hydrocarbon ring having 6 to 12 carbon atoms is more preferable, and a benzene ring is still more preferable.

Examples of the repeating unit having an aromatic ring include a repeating unit derived from (meth)acrylate having an aromatic ring, a repeating unit derived from styrene, and a repeating unit derived from a polymerizable styrene derivative.

Examples of the (meth)acrylate having an aromatic ring include benzyl (meth)acrylate, phenethyl(meth)acrylate, and phenoxyethyl(meth)acrylate.

Examples of the styrene and the polymerizable styrene derivative include styrene, methylstyrene, vinyltoluene, tert-butoxystyrene, acetoxystyrene, styrene dimer, and styrene trimer.

The (meth)acrylic resin may have a repeating unit having an alicyclic group.

The repeating unit having an alicyclic group may be a repeating unit derived from a (meth)acrylic acid ester. In other words, the repeating unit having an alicyclic group may be a repeating unit derived from a (meth)acrylic acid ester having an alicyclic group.

The alicyclic ring may be a monocycle or a polycycle.

Examples of the alicyclic ring include a dicyclopentanyl ring, a dicyclopentenyl ring, an isobornyl ring, an adamantane ring, and a cyclohexyl ring.

Examples of a monomer from which the repeating unit having an alicyclic ring is derived include dicyclopentanyl (meth)acrylate, dicyclopentenyl (meth)acrylate, isobornyl (meth)acrylate, adamantyl (meth)acrylate, and cyclohexyl (meth)acrylate.

The liquid crystal polymer is a resin exhibiting liquid crystallinity.

The liquid crystal polymer is preferably a thermotropic liquid crystal polymer. The thermotropic liquid crystal polymer refers to a polymer which exhibits liquid crystallinity in a predetermined temperature range.

The thermotropic liquid crystal polymer may be any liquid crystal polymer which can be melt-molded; and examples thereof include thermoplastic liquid crystal polyester and thermoplastic polyester amide in which an amide bond is introduced into the thermoplastic liquid crystal polyester.

The liquid crystal polymer preferably has a repeating unit having an aromatic ring.

As the aromatic ring, an aromatic hydrocarbon ring is preferable, an aromatic hydrocarbon ring having 6 to 12 carbon atoms is more preferable, and a benzene ring is still more preferable.

As a monomer from which the repeating unit having an aromatic ring is derived, p-hydroxybenzoic acid, 4,4′-dihydroxybiphenyl, hydroquinone, terephthalic acid, or isophthalic acid is preferable.

The liquid crystal polymer preferably includes two or more kinds of repeating units derived from compounds selected from p-hydroxybenzoic acid, 4,4′-dihydroxybiphenyl, hydroquinone, terephthalic acid, and isophthalic acid; and more preferably includes four or five kinds of repeating units derived from the compounds.

The liquid crystal polymer may include a repeating unit derived from a compound other than the above-described compounds.

Examples of other compounds include aromatic dicarboxylic acids such as 2,6-naphthalenedicarboxylic acid, 4,4′-diphenyldicarboxylic acid, 1,2-bis(phenoxy)ethane-4,4′-dicarboxylic acid, 1,2-bis(2-chlorophenoxy)ethane-4,4′-dicarboxylic acid, 4,4′-diphenylether dicarboxylic acid, 3,3′-diphenyldicarboxylic acid, and 2,2′-diphenyldicarboxylic acid; aliphatic dicarboxylic acids such as adipic acid, azelaic acid, sebacic acid, and dodecanedioic acid; alicyclic dicarboxylic acids such as hexahydroterephthalic acid; aromatic diols such as 3,3′,5,5′-tetramethyl-4,4′-dihydroxybiphenyl, t-butylhydroquinone, phenylhydroquinone, 2,6-dihydroxynaphthalene, 2,7-dihydroxynaphthalene, 2,2-bis(4-hydroxyphenyl)propane, 4,4′-dihydroxydiphenyl ether, chlorohydroquinone, 3,4′-dihydroxybiphenyl, 4,4′-dihydroxydiphenyl sulfone, 4,4′-dihydroxydiphenyl sulfide, 4,4′-dihydroxybenzophenone, and 3,4′-dihydroxybiphenyl; aliphatic and alicyclic diols such as ethylene glycol, propylene glycol, 1,4-butanediol, cyclohexanedimethanol, 1,6-hexanediol, neopentyl glycol, and 1,4-cyclohexanediol; aromatic hydroxycarboxylic acids such as 6-hydroxy-2-naphthoic acid and m-hydroxybenzoic acid; aromatic aminocarboxylic acids such as p-aminobenzoic acid and 6-amino-2-naphthoic acid; diamines aromatic such as 1,4-phenylenediamine, 4,4′-diaminobiphenyl, and 2,6-diaminonaphthalene; and aromatic hydroxylamines such as p-aminophenol.

Examples of the liquid crystal polymer include liquid crystal polymers described in JP2006-299254A and WO2015/064437A.

Examples of the polyethersulfone, the polyarylate, the polyether imide, the polybenzimidazole, the polyphenylsulfone, the polycarbonate, the acrylonitrile-butadiene-styrene resin, and the polyphenylene sulfide include known resins.

Examples of the resin also include known resins other than the above-described various resins.

A weight-average molecular weight (Mw) of the resin is preferably 2,000 to 500,000 and more preferably 5,000 to 100,000.

A number-average molecular weight (Mn) of the resin is preferably 800 to 250,000 and more preferably 2,000 to 50,000.

A dispersity (Mw/Mn) of the resin is preferably 1.0 to 3.5 and more preferably 2.0 to 3.0.

The resin may be used alone or in combination of two or more kinds thereof.

A content of the resin is preferably 5.0% by mass or more, and more preferably 10.0% by mass or more with respect to the total solid content of the composition. The upper limit thereof is preferably 50.0% by mass or less, and more preferably 40.0% by mass or less.

### [Filler X]

The composition contains a filler X.

The filler X is a filler surface-modified with a surface modifier. In other words, a filler constituting the filler X is surface-modified with a surface modifier.

The content of the filler X is 50.0% by mass or more with respect to the total solid content of the composition, preferably 60.0% by mass or more, and more preferably 70.0% by mass or more. The upper limit thereof is preferably 90.0% by mass or less, and more preferably 80.0% by mass or less.

The average particle diameter of the filler X is 300 nm or less, preferably 200 nm or less, and more preferably 150 nm or less. The lower limit thereof is preferably more than 0 nm, more preferably 5 nm or more, and still more preferably 10 nm or more.

The average particle diameter of the filler X is calculated by the following particle diameter measuring method.

Particle diameter measuring method: the composition is applied onto a base material to form a coating film, a rectangular region of 3 μm×10 μm in a cross section of the coating film along a normal direction of a surface of the coating film is observed with a scanning electron microscope, an operation of measuring a major diameter of all the fillers X observed in the region is performed at five different locations on the coating film, and an arithmetic mean value of all major diameters of the fillers X measured in each operation is obtained as the average particle diameter of the filler X.

The procedure of the particle diameter measuring method described above will be described in detail.

First, the composition is applied onto a base material to form a coating film. A thickness of the coating film is preferably 3 μm or more. As the base material to be used, a glass substrate is used. In a case of forming the coating film, a drying treatment may be performed as necessary.

A cross section of the obtained coating film along the normal direction of a surface (surface opposite to the substrate side) of the coating film is cut out, a rectangular region of 3 μm×10 μm in the cross section is observed with a scanning electron microscope, and a major diameter of all the fillers X observed in the region is measured. As the scanning electron microscope, S-4800 manufactured by Hitachi High-Tech Corporation is used. In addition, a magnification in the observation is 50,000 times.

The above-described operation is performed at five different positions on the coating film, and an average value (arithmetic mean value) of the major diameters of all the fillers X measured in each operation is defined as the average particle diameter of the filler X.

The above-described major diameter refers to a length of the longest line segment among line segments connecting any two points on a contour line of the filler X in the observation image.

In addition, in a case where the fillers X are aggregated in the observation image to constitute an aggregate, the major diameter of each filler X constituting the aggregate is measured.

The content of the surface modifier is 3.0% by mass or less, preferably 2.5% by mass or less, more preferably less than 2.0% by mass, and still more preferably 1.5% by mass or less with respect to the total mass of the filler X. The lower limit thereof is preferably more than 0% by mass, and more preferably 0.5% by mass or more.

The above-described content of the surface modifier means the total content of the surface modifier and a component derived from the surface modifier, covering at least a part of a surface of the filler constituting the filler X. In other words, the above-described content of the surface modifier is a value which does not include a surface modifier not covering the surface of the filler constituting the filler X, that is, a surface modifier which is liberated in the composition.

The content of the surface modifier can be measured, for example, by a method Z.

Method Z: the composition is applied onto the base material and dried such that the thickness after drying is 10 μm, thereby forming a composition layer. A temperature in the above-described drying is preferably 50° C. to 150° C. and more preferably 70° C. to 100° C. A heating time in the above-described drying is preferably 1 to 10 minutes and more preferably 2 to 7 minutes.

Next, the obtained composition layer is dissolved in a mixed solvent of methyl ethyl ketone (MEK):N-methylpyrrolidone (NMP)=1:1 to obtain a solution. Thereafter, the above-described solution is centrifuged and filtered using a filter to collect a filler before solidification, and the filler before solidification is further dried to obtain a filler for measurement. A temperature in the above-described solidification is preferably 50° C. to 150° C. and more preferably 70° C. to 100° C. A heating time in the above-described solidification is preferably 1 to 120 minutes and more preferably 5 to 30 minutes. The above-described filter can be appropriately selected according to the average particle diameter of the filler X.

With the above-described filler for measurement, a weight loss rate is measured three times under conditions of temperature rising (10° C./min) from room temperature to 1,000° C. in an air atmosphere using a TG-DTA device (TG/DTA7300) manufactured by Hitachi High-Tech Science Corporation, and the content of the surface modifier is calculated from the average value thereof.

The filler constituting the filler X is surface-modified with a surface modifier.

The expression “the filler constituting the filler X is surface-modified with a surface modifier” means that at least a part of the surface of the filler constituting the filler X is covered with the surface modifier, a component derived from the surface modifier, or the like. That is, it means that the filler X is obtained by covering at least a part of the surface of the filler constituting the filler X with the surface modifier or a component derived from the surface modifier. In a case where the surface modifier is a hydrolyzable compound, examples of the above-described component derived from the surface modifier include a hydrolyzate of the surface modifier and a hydrolysis condensate thereof.

It is preferable that at least a part of the surface of the filler constituting the filler X is covered with the surface modifier or the component derived from the surface modifier through a chemical bond; and it is more preferable that at least a part of the surface of the filler constituting the filler X is covered with the surface modifier through a bond of “—Si—O—”.

Examples of the surface modifier include a known surface modifier such as a silane coupling agent, a titanate-based coupling agent, and a silazane compound.

The above-described silane coupling agent is a compound having a hydrolyzable group directly bonded to an Si atom.

Examples of the above-described hydrolyzable group include an alkoxy group (preferably having 1 to 10 carbon atoms) and a halogen atom such as a chlorine atom.

The number of hydrolyzable groups directly bonded to an Si atom in the silane coupling agent is preferably 1 or more, more preferably 2 or more, and still more preferably 3 or more. The upper limit thereof is preferably 10,000 or less.

The silane coupling agent also preferably has a functional group other than the hydrolyzable group.

Examples of the functional group include a (meth)acryloyl group, a phenyl group, a silazane group, an epoxy group, an oxetanyl group, a vinyl group, a styryl group, an amino group, an isocyanate group, a mercapto group, and an acid anhydride group.

The number of functional groups included in the silane coupling agent may be 1, or 2 or more.

Examples of a method of surface-modifying the filler constituting the filler X with the surface modifier include a dry method of surface-modifying in a gas phase and a wet method of surface-modifying in a liquid phase; and a dry method is preferable from the viewpoint that dielectric characteristics are more excellent.

A shape of the filler X may be a spherical shape or a non-spherical shape (for example, a crushed shape and a fibrous shape), and a spherical shape is preferable.

Examples of the filler X include an organic filler and an inorganic filler, which are surface-modified with the surface modifier; and an inorganic filler, which is surface-modified with the surface modifier, is preferable.

Examples of the filler constituting the filler X include silicon dioxide (silica); silicate such as kaolinite, kaolin clay, calcined clay, talc, and undoped-type glass; and alumina, barium sulfate, mica powder, aluminum hydroxide, magnesium hydroxide, calcium carbonate, magnesium carbonate, magnesium oxide, boron nitride, aluminum borate, barium titanate, strontium titanate, calcium titanate, magnesium titanate, bismuth titanate, titanium oxide, barium zirconate, calcium zirconate, zirconium phosphate, cordierite, zirconium tungstate, and manganese nitride.

The filler X preferably includes at least one selected from the group consisting of silicon dioxide (silica), boron nitride, barium sulfate, and silicate, and more preferably includes silicon dioxide (silica); and it is still more preferable that the filler X is silicon dioxide (silica).

Examples of the filler X and the filler constituting the filler X include NHM-3N, NHM-4N, NHM-5N, NHM-24D, NP-3N, NP-4N, NP-5N, and NP-24D (all manufactured by TOKUYAMA CORPORATION; silicon dioxide, concentration of solid contents: 100% by mass); YA050C-MJE, Y50SP-AM1, and Y50SZ-AM1 (all manufactured by Admatechs Co.,

Ltd.; silicon dioxide, MEK slurry having a concentration of solid contents of 50% by mass); MEK-ST-ZL, MEK-ST-L, MEK-AC-5140Z, MEK-EC-2130Y, and MEK-EC-2430Z (all manufactured by Nissan Chemical Corporation; concentration of solid contents: 30% by mass); Sea Foster KE-S30 (manufactured by Nippon Shokubai Co., Ltd., silicon dioxide, concentration of solid contents: 100% by mass); SFP-20M (manufactured by Denka Company Limited; silicon dioxide, concentration of solid contents: 100% by mass); PMA-ST (manufactured by Nissan Chemical Corporation; silicon dioxide, concentration of solid contents: 100% by mass); and Barium sulfate (manufactured by Japan Solvay Company; barium sulfate, concentration of solid contents: 100% by mass).

A refractive index of the filler is preferably 0.5 to 3.0 and more preferably 1.2 to 1.8.

The refractive index can be measured by the above-described method.

The filler may be used alone or in combination of two or more kinds thereof.

### [Polymerizable Compound]

The composition may contain a polymerizable compound.

The polymerizable compound is a compound different from the above-described various components.

In a case where the composition contains a polymerizable compound (preferably, a compound having an ethylenically unsaturated group), it is preferable that the composition further contains a photopolymerization initiator described later.

The polymerizable compound is a compound having one or more polymerizable groups in one molecule.

As the polymerizable compound, a compound having an ethylenically unsaturated group is preferable; a compound having a (meth)acryloyl group, a vinyl group, or a styryl group is more preferable; and a compound having a (meth)acryloyl group is still more preferable.

The number of polymerizable groups included in the polymerizable compound is preferably 1 or 2 or more, more preferably 2 to 10, and still more preferably 2 to 6.

Examples of the polymerizable compound include a polymerizable compound having one polymerizable group in one molecule (hereinafter, also referred to as “monofunctional polymerizable compound”); a polymerizable compound having two polymerizable groups in one molecule (hereinafter, also referred to as “bifunctional polymerizable compound”); and a polymerizable compound having three or more polymerizable groups in one molecule (hereinafter, also referred to as “tri- or higher functional polymerizable compound”).

As the polymerizable compound, a bifunctional polymerizable compound or a tri- or higher functional polymerizable compound is preferable.

Examples the bifunctional polymerizable compound include polyethylene glycol (meth)acrylate, tricyclodecane dimethanol di(meth)acrylate, 1,9-nonanediol di(meth)acrylate, and 1,6-hexanediol di(meth)acrylate.

Examples of a commercially available product of the bifunctional polymerizable compound include diethylene glycol dimethacrylate (2G, manufactured by Shin-Nakamura Chemical Co., Ltd.), triethylene glycol dimethacrylate (3G, manufactured by Shin-Nakamura Chemical Co., Ltd.), polyethylene glycol #200 dimethacrylate (4G, manufactured by Shin-Nakamura Chemical Co., Ltd.), tricyclodecane dimethanol diacrylate (A-DCP, manufactured by Shin-Nakamura Chemical Co., Ltd.), tricyclodecane dimethanol diacrylate (DCP, manufactured by Shin-Nakamura Chemical Co., Ltd.), 1,9-nonandiol diacrylate (A-NOD-N, manufactured by Shin-Nakamura Chemical Co., Ltd.), 1,6-hexanediol diacrylate (A-HD-N, manufactured by Shin-Nakamura Chemical Co., Ltd.), SR205NS (manufactured by Sartomer Inc.), and SR209 (manufactured by Sartomer Inc.).

Examples of the tri- or higher functional polymerizable compound include dipentaerythritol (tri/tetra/penta/hexa) (meth)acrylate, pentaerythritol (tri/tetra) (meth)acrylate, trimethylolpropane tri (meth)acrylate, ditrimethylolpropane tetra (meth)acrylate, isocyanuric acid (meth)acrylate, and a (meth)acrylate compound of a glycerin tri (meth)acrylate skeleton.

The “(tri/tetra/penta/hexa) (meth)acrylate” has a concept including tri (meth)acrylate, tetra (meth)acrylate, penta (meth)acrylate, and hexa (meth)acrylate, and the “(tri/tetra) (meth)acrylate” has a concept including tri (meth)acrylate and tetra (meth)acrylate.

Examples of the polymerizable compound include a caprolactone-modified compound of a (meth)acrylate compound (KAYARAD (registered trademark) DPCA-20 and the like manufactured by Nippon Kayaku Co., Ltd.; and A-9300-1CL and the like manufactured by Shin-Nakamura Chemical Co., Ltd.), an alkylene oxide-modified compound of a (meth)acrylate compound (KAYARAD RP-1040 and the like manufactured by Nippon Kayaku Co., Ltd.; ATM-35E, A-9300, and the like manufactured by Shin-Nakamura Chemical Co., Ltd.; and EBECRYL (registered trademark) 135 manufactured by Daicel-Allnex Ltd.), and ethoxylated glycerin triacrylate (A-GLY-9E and the like manufactured by Shin-Nakamura Chemical Co., Ltd.).

Examples of the polymerizable compound also include urethane (meth)acrylate (preferably, tri- or higher functional urethane (meth)acrylate).

The number of polymerizable groups included in the urethane (meth)acrylate is preferably 6 or more, and more preferably 8 or more. The upper limit thereof is 20 or less.

Examples of the tri- or higher functional urethane (meth)acrylate include 8UX-015A (manufactured by Taisei Fine Chemical Co., Ltd.); UA-32P, U-15HA, and UA-1100H (all manufactured by Shin-Nakamura Chemical Co., Ltd.); AH-600 (manufactured by KYOEISHA CHEMICAL Co., LTD.); and UA-306H, UA-306T, UA-306I, UA-510H, and UX-5000 (all manufactured by Nippon Kayaku Co., Ltd.).

The polymerizable compound may be used alone or in combination of two or more kinds thereof.

A content of the polymerizable compound is preferably 30.0% by mass or less, more preferably 25.0% by mass or less, and still more preferably 20.0% by mass or less with respect to the total solid content of the composition. The lower limit thereof is preferably 1.0% by mass or more.

### [Photopolymerization Initiator]

The composition may contain a photopolymerization initiator.

The photopolymerization initiator is a compound different from the above-described various components.

Examples of the photopolymerization initiator include a photoradical polymerization initiator, a photocationic polymerization initiator, and a photoanionic polymerization initiator, and a photoradical polymerization initiator is preferable.

Examples of the photopolymerization initiator include an oxime ester compound (photopolymerization initiator having an oxime ester structure), an aminoacetophenone compound (photopolymerization initiator having an aminoacetophenone structure), a hydroxyacetophenone compound (photopolymerization initiator having a hydroxyacetophenone structure), an acylphosphine oxide compound (photopolymerization initiator having an acylphosphine oxide structure), and a bistriphenylimidazole compound (photopolymerization initiator having a bistriphenylimidazole structure).

As the photopolymerization initiator, an oxime ester compound or an aminoacetophenone compound is preferable, and an oxime ester compound is more preferable.

Examples of the oxime ester compound include 1,2-octanedione, 1-[4-(phenylthio) phenyl-,2-(O-benzoyloxime)] (product name: IRGACURE OXE-01; manufactured by BASF SE), etanone,1-[9-ethyl-6-(2-methylbenzoyl)-9H-carbazol-3-yl]-,1-(O-acetyloxime) (product name: IRGACURE OXE-02, manufactured by BASF SE), [8-[5-(2,4,6-trimethylphenyl)-11-(2-ethylhexyl)-11H-benzo[a]carbazoyl][2-(2,2,3,3-tetrafluoro propoxy)phenyl]methanone-(O-acetyloxime) (product name: IRGACURE OXE-03, manufactured by BASF SE), 1-[4-[4-(2-benzofuranylcarbonyl)phenyl]thio]phenyl]-4-methylpentanone-1-(O-acetyloxime) (product name: IRGACURE OXE-04, manufactured by BASF SE, and product name: Lunar 6, manufactured by DKSH Management Ltd.), 1-[4-(phenylthio)phenyl]-3-cyclopentylpropan-1,2-dione-2-(O-benzoyloxime) (product name: TR-PBG-305, manufactured by Changzhou Tronly New Electronic Materials Co., Ltd.), 1,2-propanedione, 3-cyclohexyl-1-[9-ethyl-6-(2-furanylcarbonyl)-9H-carbazole-3-yl]-, 2-(O-acetyloxime) (product name: TR-PBG-326, manufactured by Changzhou Tronly New Electronic Materials Co., Ltd.), and 3-cyclohexyl-1-(6-(2-(benzoyloxyimino) hexanoyl)-9-ethyl-9H-carbazole-3-yl)-propan-1,2-dione-2-(O-benzoyloxime) (product name: TR-PBG-391, manufactured by Changzhou Tronly New Electronic Materials Co., Ltd.).

Examples of the aminoacetophenone compound include 2-(dimethylamino)-2-[(4-methylphenyl)methyl]-1-[4-(4-morpholinyl)phenyl]-1-butanone (product name: Omnirad 379EG; Omnirad (Irgacure) series are manufactured by IGM Resins B.V.), 2-methyl-1-(4-methylthiophenyl)-2-morpholinopropan-1-one (product name: Omnirad 907), and APi-307 (1-(biphenyl-4-yl)-2-methyl-2-morpholinopropan-1-one, manufactured by Shenzhen UV-ChemTech Co., Ltd.).

Examples of the photopolymerization initiator also include 2-hydroxy-1-{4-[4-(2-hydroxy-2-methyl-propionyl)-benzyl]phenyl}-2-methyl-propan-1-one (product name: Omnirad 127), 2-benzyl-2-dimethylamino-1-(4-morpholinophenyl)-butanone-1 (product name: Omnirad 369), 2-hydroxy-2-methyl-1-phenyl-propan-1-one (product name: Omnirad 1173), 1-hydroxy-cyclohexyl-phenyl-ketone (product name: Omnirad 184), 2,2-dimethoxy-1,2-diphenylethane-1-one (product name: Omnirad 651), 2,4,6-trimethylbenzoyl-diphenylphosphine oxide (product name: Omnirad TPO H), and bis(2,4,6-trimethylbenzoyl)phenylphosphine oxide (product name: Omnirad 819).

Examples the photopolymerization initiator also include photopolymerization initiators described in paragraphs 0031 to 0042 of JP2011-095716A and paragraphs 0064 to 0081 of JP2015-014783A.

The photopolymerization initiator may be used alone or in combination of two or more kinds thereof.

A content of the photopolymerization initiator is preferably 10.0% by mass or less, more preferably 5.0% by mass or less, and still more preferably 1.0% by mass or less with respect to the total solid content of the composition. The lower limit thereof is preferably 0.1% by mass or more.

### [Compound Y]

The composition may contain a compound Y.

The compound Y is a compound which does not have an ethylenically unsaturated group and has a boiling point of 300° C. or higher.

The compound Y is a compound different from the above-described various components (for example, the photopolymerization initiator and the like).

By containing the compound Y in the composition, in a case where a transfer film having a composition layer formed of the composition is bonded (laminated) to an adherend, and a pattern is formed by an exposure treatment, a development treatment, and a heating treatment after the development, the compound Y functions as a component for ensuring plasticity of the resin such as the resin X in the photosensitive layer, and is removed by volatilization by being subjected to the heating treatment after the development, and thus is likely to be hardly remain in the system of the pattern.

The boiling point of the compound Y is 300° C. or higher, preferably 350° C. or higher. The upper limit thereof is preferably 500° C. or lower, more preferably 480° C. or lower, and still more preferably 450° C. or lower.

In the present specification, the above-described boiling point of the compound Y is a value obtained by the following measuring method.

In a case where the compound Y is distilled under normal pressure (760 mmHg), a temperature of a gas at a point in time when condensation of the evaporated gas starts is defined as the boiling point (measured at 23° C. to 300° C.; temperature rising rate: 1° C./min).

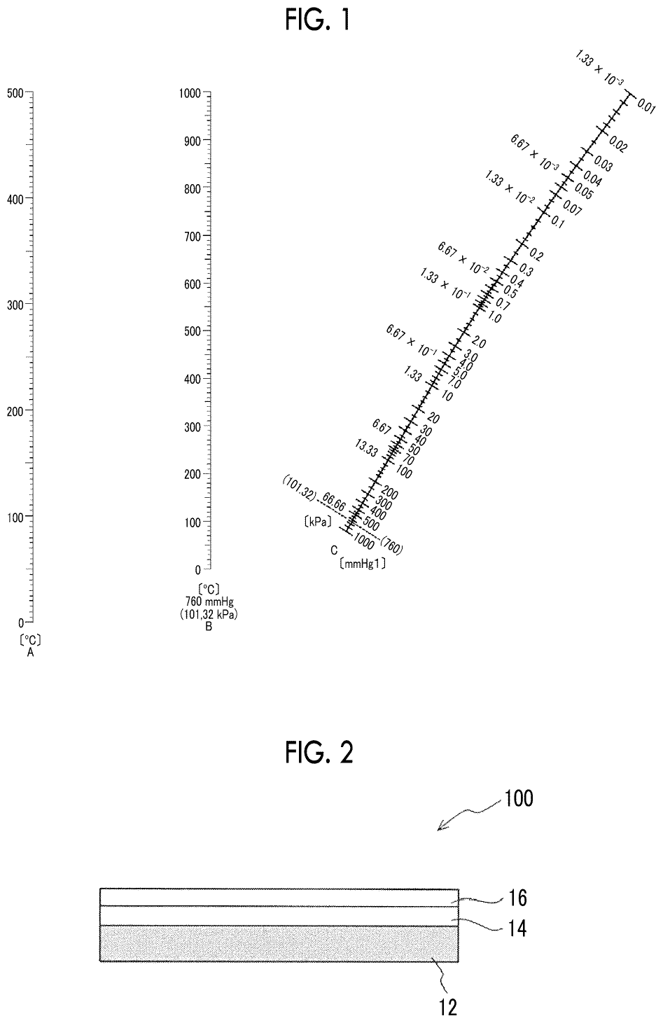

The compound Y is distilled using a Liebig condenser, and in a case where the distillation does not start at 300° C. under normal pressure, the compound Y is distilled under reduced pressure. The same distillation is carried out in the order of an atmospheric pressure of 100 mmHg, 50 mmHg, and 5 mmHg (measured at 23° C. to 300° C.; temperature rising rate: 1° C./min; in a case where the distillation does not start at 300° C., the distillation is carried out at the next pressure), and the boiling point under normal pressure is defined as the boiling point (calculated value) obtained using a nomograph shown in FIG. 1 (source: Science of Petroleum, Vol. II, p. 1281 (1938)), from the temperature and pressure at which the condensation of the evaporated gas starts. In a case where the distillation does not start at 300° C. under 5 mmHg, the boiling point under normal pressure is considered to be higher than 500° C. The nomograph is used by a known method. Specifically, a boiling point of the A line under reduced pressure and a degree of reduction of the C line are connected by a straight line (procedure 1), a numerical value of an intersection of the straight line drawn in the procedure 1 and the B line is read (procedure 2), and this is regarded as the boiling point under normal pressure.

A molecular weight of the compound Y is preferably 200 or more, more preferably 250 or more, and still more preferably 300 or more. The upper limit is preferably 1,000 or less, more preferably 800 or less, and still more preferably 600 or less.

In a case where the compound Y has a molecular weight distribution, the above-described molecular weight of the compound Y is intended to be a weight-average molecular weight.

A viscosity of the compound Y at 25° C. is preferably 500 mPa·s or less, more preferably 300 mPa·s or less, and still more preferably 100 mPa·s or less. The lower limit thereof is preferably 0.01 mPa·s or more, more preferably 0.05 mPa·s or more, and still more preferably 0.1 mPa·s or more.

The viscosity can be measured with a B-type viscometer.

Examples of the compound Y include ethylphthalyl ethyl glycolate, dihexyl phthalate, tributyl o-acetyl citrate, benzyl 2-ethylhexyl phthalate, benzyl benzoate, hexaethylene glycol monomethyl ether, pentaethylene glycol monomethyl ether, tetraethylene glycol monomethyl ether, heptaethylene glycol monomethyl ether, octaethylene glycol monomethyl ether, nonaethylene glycol monomethyl ether, pentaethylene glycol dimethyl ether, hexaethylene glycol dimethyl ether, heptaethylene glycol dimethyl ether, octaethylene glycol dimethyl ether, nonaethylene glycol dimethyl ether, bis(2-ethylhexyl) isophthalate, triamyl phosphate, tris(2-butoxyethyl) phosphate, triethylene glycol bis(2-ethylhexanoate), tris(2-ethylhexyl) trimellitate, and bis(2-butoxyethyl) adipate.

The compound Y may be used alone or in combination of two or more kinds thereof.

The content of the compound Y is preferably 1.0% by mass or more, more preferably 3.0% by mass or more, and still more preferably 5.0% by mass or more with respect to the total solid content of the composition. The upper limit thereof is preferably less than 50.0% by mass, more preferably 35.0% by mass or less, and still more preferably 25.0% by mass or less.

The total content of the polymerizable compound and the compound Y is preferably less than 50.0% by mass, more preferably 30.0% by mass or less, and still more preferably 25.0% by mass or less with respect to the total solid content of the composition.

### [Photoacid Generator]

The composition may contain a photoacid generator.

The photoacid generator is a compound which generates an acid by light (for example, exposure light).

Examples of the photoacid generator include an ionic photoacid generator and a nonionic photoacid generator.

Examples of the ionic photoacid generator include a compound having a sulfonium structure, an onium salt compound having a diaryliodonium structure or a triarylsulfonium structure, and an ammonium salt compound having a quaternary ammonium structure. Examples of the ionic photoacid generator also include ionic photoacid generators described in paragraphs 0114 to 0133 of JP2014-085643A.

Examples of the nonionic photoacid generator include trichloromethyl-s-triazine and derivatives thereof (trichloromethyl-s-triazine which may have a substituent), a compound having a diazomethane structure, a compound having an imidosulfonate structure, and a compound having an oxime sulfonate structure. Examples of the trichloromethyl-s-triazine and derivatives thereof, the diazomethane compound, and the imidosulfonate compound include compounds described in paragraphs 0083 to 0088 of JP2011-221494A. In addition, examples of the oxime sulfonate compound include compounds described in paragraphs 0084 to 0088 of WO2018/179640A.

The photoacid generator may be used alone or in combination of two or more kinds thereof.

A content of the photoacid generator is preferably 0.1% to 10.0% by mass and more preferably 0.5% to 5.0% by mass with respect to the total solid content of the composition.

### [Surfactant]

The composition may contain a surfactant.

Examples of the surfactant include surfactants described in paragraph 0017 of JP4502784B and paragraphs 0060 to 0071 of JP2009-237362A.

Examples of the surfactant include a hydrocarbon-based surfactant, a fluorine-based surfactant, and a silicone-based surfactant. From the viewpoint of improving environmental suitability, it is preferable that the surfactant does not contain a fluorine atom. As the surfactant, a hydrocarbon-based surfactant or a silicone-based surfactant is preferable.

Examples of a commercially available product of the fluorine-based surfactant include MEGAFACE F-171, F-172, F-173, F-176, F-177, F-141, F-142, F-143, F-144, F-437, F-475, F-477, F-479, F-482, F-551-A, F-552, F-554, F-555-A, F-556, F-557, F-558, F-559, F-560, F-561, F-565, F-563, F-568, F-575, and F-780 (all of which are manufactured by DIC Corporation); EXP.MFS-324, EXP.MFS-330, EXP.MFS-578, EXP.MFS-578-2, EXP.MFS-579, EXP.MFS-586, EXP.MFS-587, EXP.MFS-628, EXP.MFS-631, EXP.MFS-603, R-41, R-41-LM, R-01, R-40, R-40-LM, RS-43, TF-1956, RS-90, R-94, RS-72-K, and DS-21 (all of which are manufactured by DIC Corporation); FLUORAD FC430, FC431, and FC171 (all of which are manufactured by Sumitomo 3M Ltd.); SURFLON S-382, SC-101, SC-103, SC-104, SC-105, SC-1068, SC-381, SC-383, S-393, and KH-40 (all of which are manufactured by AGC Inc.); and POLYFOX PF636, PF656, PF6320, PF6520, and PF7002 (all of which are manufactured by OMNOVA Solutions Inc.); FTERGENT 710FL, 710FM, 610FM, 601AD, 601ADH2, 602A, 215M, 245F, 251, 212M, 250, 209F, 222F, 208G, 710LA, 710FS, 730LM, 650AC, 681, and 683 (all of which are manufactured by NEOS COMPANY LIMITED); and U-120E (Uni-chem Co., Ltd.).

Examples of the fluorine-based surfactant include an acrylic compound which has a molecular structure including a functional group having a fluorine atom and in which the functional group having a fluorine atom is broken to volatilize a fluorine atom by applying heat to the molecular structure. Examples of such a fluorine-based surfactant include MEGAFACE DS series (manufactured by DIC Corporation; The Chemical Daily, Feb. 22, 2016; Nikkei Business Daily, Feb. 23, 2016), MEGAFACE DS-21, and the like).

In addition, the fluorine-based surfactant may be a polymer of a fluorine atom-containing vinyl ether compound having a fluorinated alkyl group or a fluorinated alkylene ether group, and a hydrophilic vinyl ether compound. The fluorine-based surfactant may be a block polymer.

As the fluorine-based surfactant, a fluorine-containing polymer compound including a repeating unit derived from a (meth)acrylate compound having a fluorine atom and a repeating unit derived from a (meth)acrylate compound having 2 or more (preferably 5 or more) alkyleneoxy groups (preferably ethyleneoxy groups or propyleneoxy groups) may be used.

In addition, examples of the fluorine-based surfactant also include a fluorine-containing polymer having a group having an ethylenically unsaturated group in a side chain. Specific examples thereof include MEGAFACE RS-101, RS-102, RS-718K, and RS-72-K (all of which are manufactured by DIC Corporation).

As the fluorine-based surfactant, from the viewpoint of improving environmental suitability, a surfactant derived from a substitute material for a compound having a linear perfluoroalkyl group having 7 or more carbon atoms, such as perfluorooctanoic acid (PFOA) and perfluorooctanesulfonic acid (PFOS), is preferable.

Examples of the hydrocarbon-based surfactant include glycerol, trimethylolpropane, trimethylolethane, and ethoxylate and propoxylate thereof (for example, glycerol propoxylate, glycerol ethoxylate, and the like), polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, and sorbitan fatty acid ester.

Examples of the hydrocarbon-based surfactant include PLURONIC (registered trademark) L10, L31, L61, L62, 10R5, 17R2, and 25R2, TETRONIC 304, 701, 704, 901, 904, and 150R1, and HYDROPALAT WE 3323 (all of which are manufactured by BASF); Solsperse 20000 (manufactured by Nippon Lubrizol Corporation); NCW-101, NCW-1001, and NCW-1002 (all of which are manufactured by FUJIFILM Wako Pure Chemical Corporation); Pionin D-1105, D-6112, D-6112-W, and D-6315 (all of which are manufactured by TAKEMOTO OIL & FAT Co., Ltd.); and OLFINE E1010, and SURFYNOL 104, 400, and 440 (all of which are manufactured by Nissin Chemical Co., Ltd.).

Examples of the silicone-based surfactant include a linear polymer including a siloxane bond, a modified siloxane polymer in which an organic group is introduced into a side chain and/or a terminal, and a polymer having a repeating unit having a hydrophilic group in a side chain and a repeating unit having a siloxane bond-containing group in a side chain. As the silicone-based surfactant, a polymer having a repeating unit having a hydrophilic group in a side chain and a repeating unit having a siloxane bond-containing group in a side chain is preferable. The above-described polymer may be either a random copolymer or a block copolymer.

As the repeating unit having a siloxane bond-containing group in a side chain, a repeating unit represented by Formula (SX1) or a repeating unit represented by Formula (SX2) is preferable.

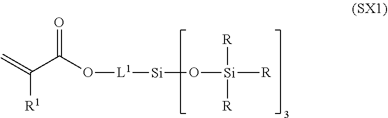

In Formula (SX1), R's each independently represent an alkyl group having 1 to 3 carbon atoms, R¹ represents a hydrogen atom or a methyl group, L¹ represents a single bond or a divalent organic group, and
in a case of a plurality of R's, R's may be the same or different from each other.

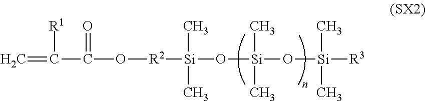

In Formula (SX2), R¹ represents a hydrogen atom or a methyl group, R² represents an alkylene group having 1 to 10 carbon atoms, R³ represents an alkyl group having 1 to 4 carbon atoms, and n represents an integer of 5 to 50.

As the repeating unit having a hydrophilic group in a side chain, a repeating unit represented by Formula (SX3) is preferable.

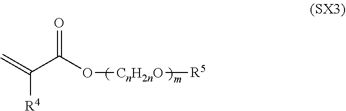

In Formula (SX3), R⁴ and R⁵ each independently represent a hydrogen atom or a methyl group, n represents an integer of 1 to 4, and q represents an integer of 1 to 100.

Examples of the silicone-based surfactant include EXP.S-309-2, EXP.S-315, EXP.S-503-2, EXP.S-505-2, and EXP.S-506 (all of which are manufactured by DIC Corporation); DOWSIL 8032 ADDITIVE, TORAY SILICONE DC3PA, TORAY SILICONE SH7PA, TORAY SILICONE DC11PA, TORAY SILICONE SH21PA, TORAY SILICONE SH28PA, TORAY SILICONE SH29PA, TORAY SILICONE SH30PA, and TORAY SILICONE SH8400 (all of which are manufactured by Dow Corning Toray Co., Ltd.); X-22-4952, X-22-4272, X-22-6266, KF-351A, K354L, KF-355A, KF-945, KF-640, KF-642, KF-643, X-22-6191, X-22-4515, KF-6004, KF-6001, KF-6002, KP-101, KP-103, KP-104, KP-105, KP-106, KP-109, KP-112, KP-120, KP-121, KP-124, KP-125, KP-301, KP-306, KP-310, KP-322, KP-323, KP-327, KP-341, KP-368, KP-369, KP-611, KP-620, KP-621, KP-626, and KP-652 (all of which are manufactured by Shin-Etsu Silicone Co., Ltd.); F-4440, TSF-4300, TSF-4445, TSF-4460, and TSF-4452 (all of which are manufactured by Momentive Performance Materials Co., Ltd.); and BYK300, BYK306, BYK307, BYK310, BYK320, BYK323, BYK325, BYK330, BYK313, BYK315N, BYK331, BYK333, BYK345, BYK347, BYK348, BYK349, BYK370, BYK377, BYK378, and BYK323 (all of which are manufactured by BYK Chemie).

Examples of the surfactant also include a nonionic surfactant.

The surfactant may be used alone or in combination of two or more kinds thereof.

A content of the surfactant is preferably 0.01% to 3.0% by mass, more preferably 0.01% to 1.0% by mass, and still more preferably 0.05% to 0.8% by mass with respect to total solid content of the composition.

### [Curing Agent]

The composition may contain a curing agent.

The curing agent is not particularly limited as long as it is, for example, a compound which accelerates curing of the various components contained in the composition.

Examples of the curing agent include an active ester curing agent, a cyanate ester curing agent, and a benzoxazine curing agent.

Examples of the active ester curing agent include EPICLON series of EXB9451, EXB9460, EXB9460S, HPC8000-65T, and EXB9416-70BK (manufactured by DIC Corporation); and DC808 and YLH1026 (manufactured by Mitsubishi Chemical Corporation).

Examples of the curing agent also include curing agents described in JP2020-154325A and JP2004-277460A.

### [Other Additives]

The composition may contain an additive other than the above-described various components.

Examples of other additives include a heterocyclic compound (for example, triazole, benzotriazole, and tetrazole, derivatives thereof, and the like; and a rust inhibitor), an aliphatic thiol compound, a thermal crosslinking compound, a polymerization inhibitor, a hydrogen donating compound, a solvent, impurities, a plasticizer, a sensitizer, an alkoxysilane compound, and a maleimide compound.

Examples of the heterocyclic compound, the aliphatic thiol compound, the thermal crosslinking compound, the polymerization inhibitor, and the hydrogen donating compound include various components described in WO2022/039027A.

Examples of the plasticizer, the sensitizer, and the alkoxysilane compound include those described in paragraphs 0097 to 0119 of WO2018/179640A.

Examples of the maleimide compound (a compound having a maleimide ring) include known maleimide compounds and maleimide compounds described in WO2022/102756A.

The solvent is not particularly limited as long as it can dissolve or disperse the various components which can be contained in the composition, other than the solvent.

Examples of the solvent include water, an alkylene glycol ether solvent, an alkylene glycol ether acetate solvent, an alcohol solvent (for example, methanol, ethanol, and the like), a ketone solvent (for example, acetone, methyl ethyl ketone, and the like), an aromatic hydrocarbon solvent (for example, toluene and the like), an aprotic polar solvent (for example, N,N-dimethylformamide and the like), a cyclic ether solvent (for example, tetrahydrofuran and the like), an ester solvent (for example, n-propyl acetate and the like), an amide solvent, a lactone solvent, and a solvent including two or more kinds thereof.

The solvent may be used alone or in combination of two or more kinds thereof.

A content of the solvent is preferably 50 to 1,900 parts by mass, more preferably 100 to 1,200 parts by mass, and still more preferably 100 to 900 parts by mass with respect to 100 parts by mass of the total solid content of the composition.

The composition may contain impurities.

Examples of the impurities include sodium, potassium, magnesium, calcium, iron, manganese, copper, aluminum, titanium, chromium, cobalt, nickel, zinc, tin, halogen, and ions of these. Since the halide ion, the sodium ion, and the potassium ion (preferably, the sodium ion and the chloride ion) are likely to be mixed in as the impurities, the content thereof is preferably set to the following content.

In a case where the composition does not contain impurities (particularly, sodium ions or chloride ions), or in a case where the composition contains impurities, a content of the impurities is usually 100 ppm by mass or less, preferably 80 ppm by mass or less, more preferably 50 ppm by mass or less, still more preferably 20 ppm by mass or less, and particularly preferably 10 ppm by mass or less with respect to the total solid content of the composition. The lower limit thereof is usually 0 ppb by mass or more with respect to the total solid content of the composition, preferably 1 ppb by mass or more, and more preferably 0.1 ppm by mass or more.

Examples of a method for adjusting the content of the impurities include a method of using raw materials having a low content of impurities as raw materials of the various components contained in the composition; a method of purifying the various components contained in the composition; and a method of preventing the impurities from being mixed in the composition during the preparation of the composition.

In particular, examples of a method for adjusting the contents of the sodium ion and the chloride ion include a method of reducing the content of the surface modifier and a method of performing the surface treatment on the filler constituting the filler X using a surface modifier having a low content of impurities.

The content of the impurities can be quantified by a known method such as inductively coupled plasma (ICP) emission spectroscopy, atomic absorption spectroscopy, and ion chromatography. In a case where ion chromatography is used, for example, using ICS-2100 manufactured by Thermo Fisher Scientific Inc. as an analysis apparatus, a measurement can be performed at a column temperature of 35° C. using IonPac AS11HC manufactured by Thermo Fisher Scientific Inc. as a column in a case where the measurement target is an anion, and using IonPac CS12 manufactured by Thermo Fisher Scientific Inc. as a column in a case where the measurement target is a cation.

In the composition, it is preferable that the content of compounds such as benzene, formaldehyde, trichlorethylene, 1,3-butadiene, carbon tetrachloride, chloroform, N,N-dimethylformamide, N,N-dimethylacetamide, and hexane is low. Specifically, the content of these compounds is preferably 100 ppm by mass or less, more preferably 20 ppm by mass or less, and still more preferably 4 ppm by mass or less with respect to the total solid content of the composition. The lower limit thereof may be 10 ppb by mass or more or 100 ppb by mass or more with respect to the total solid content of the composition.

The content of these compounds can be adjusted by the same method as that for the above-described impurities. In addition, these compounds can be quantified by a known measuring method.

Examples of a suitable aspect of the composition include the following aspect A.

Aspect A: it is preferable that the composition satisfies at least one of containing the resin having a polymerizable group (preferably an ethylenically unsaturated group) or containing a polymerizable compound (preferably a polymerizable compound having an ethylenically unsaturated group). In addition, in the above-described case, it is preferable that the composition further contains a photopolymerization initiator. The resin having an ethylenically unsaturated group is one aspect of the above-described resin.

### [Transfer Film]

The transfer film includes a temporary support, and a composition layer formed of the above-described composition.

FIG. 2 is a schematic cross-sectional view showing an example of the embodiment of the transfer film.

A transfer film 100 has a configuration in which a temporary support 12, a composition layer 14, and a cover film 16 are laminated in this order. The transfer film 100 may not include a cover film 16. In addition, the transfer film 100 may further include an interlayer described later and/or a thermoplastic resin layer described later.

Hereinafter, each member included in the transfer film will be described in detail.

### [Temporary Support]

The transfer film includes a temporary support.

The temporary support is a member which supports the composition layer, and is finally removed by a peeling treatment.

The temporary support may have a monolayer structure or a multilayer structure.

The temporary support is preferably a film and more preferably a resin film.

As the temporary support, a film which has flexibility and does not generate significant deformation, contraction, or stretching under pressure or under pressure and heating is also preferable. Examples of the above-described film include a polyethylene terephthalate film (for example, a biaxially stretched polyethylene terephthalate film and the like), a polymethyl methacrylate film, a cellulose triacetate film, a polystyrene film, a polyimide film, and a polycarbonate film; and a polyethylene terephthalate film is preferable.

In addition, it is preferable that the temporary support does not have deformation such as wrinkles and scratches.

From the viewpoint that pattern exposure through the temporary support can be performed, the temporary support preferably has high transparency. Specifically, any of transmittances at a wavelength of 313 nm, at a wavelength of 365 nm, at a wavelength of 405 nm, and at a wavelength of 436 nm is preferably 60% or more, more preferably 70% or more, still more preferably 80% or more, and most preferably 90% or more. The upper limit thereof is preferably less than 100%. Examples of a preferred value of any of the transmittances at each of the wavelengths described above include 87%, 92%, and 98%.

From the viewpoint of pattern formability during pattern exposure through the temporary support and transparency of the temporary support, it is preferable that a haze of the temporary support is small. Specifically, a haze value of the temporary support is preferably 2% or less, more preferably 0.5% or less, and still more preferably 0.1% or less. The lower limit thereof is preferably 0% or more.

From the viewpoint of pattern formability during the pattern exposure through the temporary support and transparency of the temporary support, it is preferable that the number of fine particles, foreign substances, and defects contained in the temporary support is small. The number of fine particles having a diameter of 1 μm or more, foreign substances, and defects in the temporary support is preferably 50 pieces/10 mm² or less, more preferably 10 pieces/10 mm² or less, still more preferably 3 pieces/10 mm² or less, and particularly preferably 0 piece/10 mm².

A thickness of the temporary support is preferably 5 to 200 μm, and from the viewpoint of ease of handling and general-purpose properties, it is more preferably 5 to 150 μm, still more preferably 5 to 50 μm, and particularly preferably 5 to 35 μm.

The thickness of the temporary support can be calculated as an average value of 5 random points measured by cross-sectional observation with a scanning electron microscope (SEM).

In order to improve adhesiveness between the temporary support and the composition layer, a surface of the temporary support in contact with the composition layer may be surface-modified by UV irradiation, corona discharge, plasma, or the like.

In a case where the surface is modified by UV irradiation, an exposure amount of the UV irradiation is preferably 10 to 2,000 mJ/cm² and more preferably 50 to 1,000 mJ/cm².

Examples of a light source for the UV irradiation include a low pressure mercury lamp, a high pressure mercury lamp, an ultra-high pressure mercury lamp, a carbon arc lamp, a metal halide lamp, a xenon lamp, a chemical lamp, an electrodeless discharge lamp, and a light emitting diode, all of which emit light in a wavelength range of 150 to 450 nm.

The lamp output and the illuminance can be appropriately adjusted.

Examples of the temporary support include a biaxial stretching polyethylene terephthalate film having a thickness of 16 μm, a biaxial stretching polyethylene terephthalate film having a thickness of 12 μm, and a biaxial stretching polyethylene terephthalate film having a thickness of 9 μm.

The temporary support may be a recycled product. Examples of the recycled product include a product obtained by washing and chipping used films and the like, and forming the obtained material into a film. Examples of a commercially available product of the recycled product include Ecouse series (manufactured by Toray Industries, Inc.).

Examples of the temporary support include those described in paragraphs 0017 and 0018 of JP2014-085643A, paragraphs 0019 to 0026 of JP2016-027363A, paragraphs 0041 to 0057 of WO2012/081680A, and paragraphs 0029 to 0040 of WO2018/179370A, the contents of which are incorporated in the present specification.

The temporary support may have a layer (lubricant layer) containing fine particles on one or both surfaces of the temporary support, from the viewpoint of imparting handleability. An average diameter of the fine particles contained in the lubricant layer is preferably 0.05 to 0.8 μm. A thickness of the lubricant layer is preferably 0.05 to 1.0 μm.

Examples of a commercially available product of the temporary support include LUMIRROR 16FB40, LUMIRROR 16KS40, LUMIRROR #38-U48, LUMIRROR #75-U34, and LUMIRROR #25T60 (all of which are manufactured by Toray Industries, Inc.); and COSMOSHINE A4100, COSMOSHINE A4160, COSMOSHINE A4300, COSMOSHINE A4360, and COSMOSHINE A8300 (all of which are manufactured by TOYOBO Co., Ltd.).

### [Composition Layer]

The composition layer is a layer formed of the above-described composition.

Examples of various components which can be contained in the composition layer include various components which can be contained in the above-described composition, other than the solvent.

However, suitable numerical ranges of contents of the various components in the composition layer are the same as suitable ranges in which “content (% by mass) of various components with respect to the total solid content of the composition” described above is read as “content (% by mass) of various components with respect to the total mass of the composition layer”. Specifically, the description that “the content of the resin is preferably 5.0% by mass or more with respect to the total solid content of the composition” is read as “the content of the resin is preferably 5.0% by mass or more with respect to the total mass of the composition layer”.

An average thickness of the composition layer is preferably 0.5 to 40 μm, more preferably 0.5 to 25 μm, and still more preferably 3 to 20 μm. In a case where the average thickness of the composition layer is 40 μm or less, resolution of the pattern is excellent, which is preferable. In a case where the average thickness of the composition layer is 0.5 μm or more, reliability is excellent, which is preferable.

### [Interlayer and Thermoplastic Resin Layer]

The transfer film may include an interlayer and/or a thermoplastic resin layer.

In a case where the transfer film includes an interlayer and/or a thermoplastic resin layer, it is preferable that the transfer film includes the interlayer and/or the thermoplastic resin layer between the temporary support and the composition layer.

Examples of the interlayer and the thermoplastic resin layer include those described in paragraphs 0164 to 0204 of WO2021/166719A, the contents of which are incorporated in the present specification.

### [Cover Film]

The transfer film may include a cover film.

The number of fisheyes with a diameter of 80 μm or more in the cover film is preferably 5 pieces/m² or less, and more preferably 0 pieces/m² or less. The “fisheye” means that, in a case where a material is hot-melted, kneaded, extruded, biaxially stretched, cast and/or the like to produce a film, foreign substances, undissolved substances, oxidatively deteriorated substances, and/or the like of the material are incorporated into the film.

The number of particles having a diameter of 3 μm or more, included in the cover film, is preferably 30 particles/mm² or less, more preferably 10 particles/mm² or less, still more preferably 5 particles/mm² or less, and particularly preferably 0 particles/mm² or less. As a result, it is possible to suppress defects caused by ruggedness due to the particles contained in the cover film being transferred to the composition layer.

An arithmetic average roughness Ra of a surface of the cover film is preferably 0.01 μm or more, more preferably 0.02 μm or more, and still more preferably 0.03 μm or more. In a case where Ra is within the above-described range, for example, in a case where the transfer film has a long shape, take-up property in a case of winding the transfer film is excellent. In addition, from the viewpoint of suppressing defects during transfer, an arithmetic average roughness Ra is preferably less than 0.50 μm, more preferably 0.40 μm or less, and still more preferably 0.30 μm or less.

Examples of the cover film include a polyethylene terephthalate film, a polypropylene film, a polystyrene film, and a polycarbonate film.

Examples of the cover film include films described in paragraphs 0083 to 0087 and 0093 of JP2006-259138A.

Examples of the cover film include ALPHAN (registered trademark) FG-201 (manufactured by Oji F-Tex Co., Ltd.), ALPHAN (registered trademark) E-201F (manufactured by Oji F-Tex Co., Ltd.), Cerapeel (registered trademark) 25WZ (manufactured by TORAY ADVANCED FILM CO., LTD.), and LUMIRROR (registered trademark) 16QS62 (16KS40) (manufactured by Toray Industries, Inc.).

The cover film may be a recycled product. Examples of the recycled product include a product obtained by washing and chipping used films and the like, and forming the obtained material into a film. Examples of a commercially available product of the recycled product include Ecouse series (manufactured by Toray Industries, Inc.).

### [Other Layers]

The transfer film may include a layer other than the above-described layers.

Examples of other layers include a layer of high refractive index. Examples of the layer of high refractive index include those described in paragraphs 0168 to 0188 of WO2021/187549A, the contents of which are incorporated in the present specification.

### [Method for Manufacturing Transfer Film]

As a method for manufacturing the transfer film, a known manufacturing method can be adopted.

As the method for manufacturing the transfer film, a method in which the composition is applied onto the temporary support to form the composition layer is preferable.

Examples of the method for manufacturing the transfer film include a method including a step of applying a composition onto a surface of the temporary support to form a coating film, and then drying the coating film to form the composition layer.

It is also preferable that the method for manufacturing the transfer film further includes a step of pressure-bonding the cover film onto the obtained composition layer. In addition, the obtained transfer film may be wound and stored in a roll form. The roll-shaped transfer film is provided as it is in a bonding step with the base material in a roll-to-roll method.

As described above, the transfer film may include an interlayer and/or a thermoplastic resin layer.

Examples of a composition for forming the interlayer, a method for forming the interlayer, a composition for forming the thermoplastic resin layer, and a method for forming the thermoplastic resin layer include paragraphs 0133 to 0136 and paragraphs 0143 and 0144 of WO2021/033451A, the contents of which are incorporated in the present specification.

As a method of forming the composition layer, a known method can be used, and examples thereof include a method of forming the composition layer by applying and drying a composition. The above-described composition is the composition according to the embodiment of the present invention described above.

Examples of an applying method include slit coating, spin coating, curtain coating, and inkjet coating.

It is preferable that the composition further contains a solvent. The solvent has the same meaning as the solvent which can be contained in the above-described composition, and a suitable aspect thereof is also the same.

### [Applications]

A pattern (film) obtained from the composition layer formed of the above-described composition or the above-described transfer film can be applied to various applications. For example, these can be applied to an electrode protective film, an insulating film, a flattening film, an overcoat film, a hard coat film, a passivation film, a partition wall, a spacer, a microlens, an optical filter, an antireflection film, an etching resist, or a plating member.

More specific examples thereof include a protective film or an insulating film for a touch panel electrode, a protective film or an insulating film for a printed wiring board, a protective film or an insulating film for a TFT substrate, an interlayer insulating film in a build-up substrate of a semiconductor package, an organic interposer, a color filter, an overcoat film for a color filter, and an etching resist and a plating member for a wiring line formation.

[Method for manufacturing laminate]

A method for manufacturing a laminate is not particularly limited as long as it is a method using the above-described composition or the above-described transfer film. Examples of the method for manufacturing a laminate include known manufacturing methods such as a method for manufacturing a build-up substrate; and a manufacturing method including a step Z1 to a step Z3 is preferable, and a manufacturing method including a step Z1 to a step Z4 is more preferable.
Step Z1: step of forming a composition layer on a base material using the composition or the transfer film
Step Z2: step of forming a pattern having a via in the above-described composition layer
Step Z3: step of heating or exposing the above-described pattern
Step Z4: step of forming a circuit pattern on the obtained pattern

In addition, the method for manufacturing a laminate is preferably a method for manufacturing a laminate, including the step Z1 to the step Z4, further including a step Z5 of forming a composition layer on the laminate manufactured in the step Z4 using a composition or a transfer film, and repeatedly performing the step Z2 to the step Z5.

### <Step Z1>

The step Z1 is a step of forming a composition layer on a base material using the composition or the transfer film.

In a case where the composition is used, the step Z1 is preferably a step of applying the composition onto a base material to form a composition layer. Examples of a method of applying the composition include the method of forming the composition layer in the above-described method for manufacturing the transfer film.

In a case where the transfer film is used, the step Z1 is preferably a step of bringing a surface of the composition layer on a side opposite to the temporary support side in the transfer film into contact with a base material to bond the transfer film to the base material. Examples of the bonding method of the transfer film include known transfer methods and known laminating methods using a known laminator such as a laminator, a vacuum laminator, and an auto-cut laminator; and a method in which pressurization and heating are performed using a roll or the like is preferable. A laminating temperature is preferably 70° C. to 130° C.

In addition, in a case where the transfer film has a cover film, it is preferable that the step Z1 is performed after the cover film is peeled off from the transfer film.

(Base material)

Examples of the base material include a glass substrate, a glass epoxy substrate, a silicon substrate, a resin substrate, and a substrate having a conductive layer; and a substrate having a conductive layer is preferable.

The base material may be composed of a translucent substrate such as a glass substrate, and for example, tempered glass typified by Gorilla glass of Corning Incorporated may be used. In addition, examples of the material contained in the above-described base material also include materials described in JP2010-086684A, JP2010-152809A, and JP2010-257492A.

As the resin substrate, a resin film having a small optical distortion and/or a high transparency is preferable. Specific examples thereof include polyester, polyethylene terephthalate (PET), polyethylene naphthalate, polycarbonate, triacetyl cellulose, a cycloolefin polymer, and polyimide.

As the substrate having a conductive layer, from the viewpoint that it is possible to manufacture by a roll-to-roll method, a resin substrate having a conductive layer is preferable and a resin film having a conductive layer is more preferable.

In addition, the substrate having a conductive layer may be a laminate obtained by the above-described method for manufacturing a laminate.

Examples of the conductive layer include known conductive layers used for a circuit wiring or a touch panel wiring.

As the conductive layer, from the viewpoint of conductivity and fine line formability, one or more layers selected from the group consisting of a metal layer (for example, a metal foil or the like), a conductive metal oxide layer, a graphene layer, a carbon nanotube layer, and a conductive polymer layer are preferable, a metal layer is more preferable, and a copper layer or a silver layer is still more preferable. In addition, the conductive layer may be one or two or more layers. The conductive layer may be used alone or in combination of two or more kinds thereof.

Examples of a material of the conductive layer include simple substances of metal and conductive metal oxides.

Examples of the simple substance of metal include Al, Zn, Cu, Fe, Ni, Cr, Mo, Ag, and Au.

Examples of the conductive metal oxide include indium tin oxide (ITO), indium zinc oxide (IZO), and SiO₂. The “conductive” means that a volume resistivity is less than 1×10⁶ Ω·cm, preferably less than 1×10⁴ Ω·cm.

The conductive layer may be patterned.

Examples of a method for manufacturing the patterned conductive layer include a subtractive method such as an etching method, and an additive method. Examples of the etching method include a method by wet etching, which is described in paragraphs 0048 to 0054 of JP2010-152155A, and a method by dry etching such as a known plasma etching. In addition, the etching method may be a method using an etching resist.

### <Step Z2>

The step Z2 is step of forming a pattern having a via in the above-described composition layer.

The pattern having a via may be formed only in the composition layer or may be formed in both the composition layer and the base material.

Examples of a method of forming the pattern having a via include a method using a drill, a laser, and plasma.

In addition, in a case where the composition layer has photosensitivity, it is preferable that the method of forming the pattern having a via includes a step of exposing the composition layer in a patterned manner, a step of developing the exposed composition layer with a developer to form a pattern, and a step of subjecting the conductive layer in a region where the pattern is not disposed to an etching treatment. In addition, it is more preferable that the method of forming the pattern having a via includes a step of curing the pattern between the step of forming the pattern and the step of performing the etching treatment.

The exposure may be performed from the side opposite to the base material of the composition layer, or may be performed from the base material side of the composition layer.

As the composition which forms the composition layer having photosensitivity, the above-described aspect A is preferable.

A light source used for the exposure may be selected as long as it irradiates various components (for example, a resin, a polymerizable compound, a photopolymerization initiator, a photoacid generator, and the like) which can be photo-sensitized in the composition layer with light in a photosensitive wavelength range (for example, light in a wavelength range of 254 nm, 313 nm, 365 nm, 405 nm, and the like).

Specific examples thereof include an ultra-high pressure mercury lamp, a high pressure mercury lamp, a metal halide lamp, and a light emitting diode (LED).

An exposure amount is preferably 5 to 200 mJ/cm² and more preferably 10 to 200 mJ/cm².

In the step Z2, the temporary support may be peeled off and then exposed, or the temporary support may be exposed through the temporary support and then peeled off.

From the viewpoint of preventing mask contamination due to contact between the composition layer and the mask and avoiding an influence of foreign substance adhering to the mask on the exposure, it is preferable to perform the pattern exposure without peeling off the temporary support. The pattern exposure may be an exposure through a mask or a direct exposure using a laser or the like.

Examples of the mask include a quartz mask, a soda-lime glass mask, and a film mask.

From the viewpoint of excellent dimensional accuracy, a quartz mask is preferable, and from the viewpoint that it is easy to increase the size, a film mask is preferable.

As a material of the film mask, a polyester film is preferable, and a polyethylene terephthalate film is more preferable. Specific examples of the material of the film mask include XPR-7S SG (manufactured by Fujifilm Global Graphic Systems).

The pattern having a via may be a through-hole or a via hole.

Examples of a shape of the via of the pattern include, as a cross-sectional shape, a quadrangular shape, a trapezoidal shape, and an inverted trapezoidal shape; and as a front shape, a circular shape and a quadrangular shape (a shape in a case where the via is observed from a direction in which the via bottom is seen). Among these, an inverted trapezoidal shape is preferable as the cross-sectional shape from the viewpoint of improving attachability of the copper plating to the via wall surface.

A size (diameter) of the via is preferably 300 μm or less, more preferably 100 μm or less, still more preferably 50 μm or less, and particularly preferably 5 μm or less. The lower limit thereof is preferably 1 μm or more.

The number of the above-described vias may be 1 or 2 or more, and is preferably 2 or more.

### <Step Z3>

The step Z3 is a step of heating or exposing the composition layer.

The step Z3 is preferably a step of curing the composition layer.

A heating temperature is preferably 100° C. to 300° C., and a heating time is preferably 10 minutes to 10 hours.

Examples of the exposing method include the exposing method in the step Z2.

### [Step Z4]

The step Z4 is a step of forming a circuit pattern on the above-described pattern.

As a method of forming the circuit pattern, a semi-additive process is preferable from the viewpoint that a fine wiring can be formed.

As the semi-additive process, for example, first, a seed layer is formed by performing an electroless copper plating treatment on the entire surface of the via bottom, the via wall surface, and the pattern in the pattern having a via using a palladium catalyst or the like.

The above-described seed layer is for forming a power feeding layer for performing the electrolytic copper plating, and a thickness of the seed layer is preferably 0.1 to 2.0 μm. In a case where the thickness of the above-described seed layer is 0.1 μm or more, the tendency is that the deterioration in connection reliability during the electroless copper plating can be suppressed, and in a case where the thickness of the above-described seed layer is 2.0 μm or less, the tendency is that it is not necessary to increase the etching amount in a case of flash-etching the seed layer between the wiring lines, and the damage to the wiring lines during the etching can be suppressed.

The electroless copper plating treatment is performed by precipitating metallic copper on the surface of the pattern having a via by a reaction between copper ions and a reducing agent. Examples of the electroless plating treatment method and the electrolytic plating treatment method include known plating treatment methods.

As the catalyst in the electroless plating treatment, a palladium-tin mixed catalyst is preferable. An average primary particle diameter of the above-described mixed catalyst is preferably 10 nm or less. In addition, it is preferable that the plating liquid for the electroless plating treatment contains hypophosphorous acid (reducing agent).

Examples of the electroless copper plating liquid include “MSK-DK” manufactured by Atotech Japan K.K. and “SULKACUP (registered trademark) PEA ver. 4” series manufactured by Uemura Kogyo Co., Ltd.

The method for manufacturing a laminate may include a roughening step of roughening a pattern having a via. It is preferable that the above-described roughening step is performed after the above-described step Z3 and before the above-described step Z4.

By performing the roughening step, the above-described patterned surface can be roughened, and the adhesiveness with the circuit wiring can be improved. In addition, the smearing can be removed at the same time.

Examples of the roughening step include a known desmutting treatment, and a treatment of bringing the roughening liquid into contact is preferable.

Examples of the roughening liquid include a roughening liquid containing chromium and sulfuric acid, a roughening liquid containing an alkali permanganate (for example, a sodium permanganate roughening liquid or the like), and a roughening liquid containing sodium fluoride, chromium, and sulfuric acid.

From the viewpoint that the electrical insulation reliability, the curing characteristics, and the adhesion strength to the plated copper can be improved, it is preferable to perform a heating treatment after the formation of the circuit pattern.

A heating temperature is preferably 150° C. to 240° C., and a heating time is preferably 15 to 500 minutes.

### [Laminate]

The laminate is a laminate obtained by the above-described method for manufacturing a laminate.

The cured film may be used as an insulating film, and may be used as an organic interposer or an insulating film in a so-called build-up substrate.

The above-described laminate is used, for example, in a semiconductor device. Examples of the semiconductor device include various semiconductor devices such as a semiconductor package provided in an electrical product (for example, a computer, a mobile phone, a digital camera, and a television) and a vehicle (for example, a motorcycle, an automobile, a train, a ship, and an airplane).

### [Cured Film]

The cured film is a film obtained by curing the above-described composition.

Examples of the curing method include a heating method and an exposure method in the step Z3.

The composition forming the cured film is not particularly limited as long as it is the above-described composition, but it is preferable to contain at least one selected from the group consisting of the phenol resin and the epoxy resin.

### EXAMPLES

Hereinafter, the present invention will be further described in detail with reference to Examples. The material, the amount used, the proportion, the process contents, the process procedure, and the like shown in the following examples can be appropriately changed, within a range not departing from the gist of the present invention. Therefore, the scope of the present invention should not be construed as being limited to Examples.

In Examples and Comparative Examples, unless otherwise specified, “part” and “%” mean “part by mass” and “% by mass”, respectively.

### [Preparation of Composition]

Various components were mixed such that the solid content proportion was as shown in the table, and the mixture was further diluted so that the concentration of solid contents was 30% by mass, the concentration of methyl ethyl ketone (MEK) was 20% by mass, and the concentration of N-methylpyrrolidone (NMP) was 50% by mass, thereby preparing a composition. In a case where the silica was not a slurry (in a case of being powder), the silica was dispersed in a 50% by mass MEK solution and then finally mixed with the other components to prepare a composition. In addition, the contents of the sodium ion and the chloride ion in the composition were adjusted using the above-described method of adjusting the content of the impurities as necessary.

### [Resin]

A-1: phenol resin, TR4020G, manufactured by ASAHI YUKIZAI CORPORATION
A-2: epoxy resin, ZX1059 (mixed product (1:1) of a bisphenol A-type epoxy resin and a bisphenol F-type epoxy resin), manufactured by NIPPON STEEL Chemical & Material Co., Ltd.
A-3: a polyphenylene ether resin having a branched structure, synthesized by the following method;

1.3 g of di-μ-hydroxo-bis[(N,N,N′,N′-tetramethylethylenediamine) copper (II)]chloride (Cu/TMEDA) and 1.59 mL of tetramethylethylenediamine (TMEDA) were added to a 1,500 mL two-neck eggplant flask and sufficiently dissolved, and oxygen was supplied at 10 mL/min. 52.5 g of 2,6-dimethylphenol and 6.5 g of 2-allylphenol were dissolved in 0.75 L of toluene to prepare a raw material solution. The raw material solution was added dropwise to the above-described eggplant flask, and the reaction was carried out at 45° C. for 5 hours while stirring at a rotation speed of 600 rpm. After completion of the reaction, the precipitate was reprecipitated with a mixed solution of 10 L of methanol and 11 mL of concentrated hydrochloric acid, collected by filtration, and dried at 70° C. for 24 hours to obtain the resin A-3. A number-average molecular weight of the resin A-3 was 25,000, and a weight-average molecular weight thereof was 66,000.
A-4: silicone resin, organopolysiloxane having an average unit formula M₂D₃ and having 0.23 mol of vinyl groups per 100 g; viscosity: 2,000 mPa·s
M: (CH₂═CH)(CH₃)(C₆H₅)SiO_{1/2}
D: (C₆H₅)₂SiO_{2/2}
A-5: benzocyclobutene resin, cyclotene resin XUR-JW-1148-200201415-47, manufactured by Dow Chemical Company
A-6: acrylic resin, styrene/acrylic acid=71% by mass/29% by mass, synthesized by the following method;

1-methoxy-2-acetoxypropane (PGMEA, 60 parts) and propylene glycol monomethyl ether (PGME, 240 parts) were placed in a flask having a capacity of 2,000 mL to prepare a mixed solution. The obtained mixed solution was heated to 90° C. while stirring at a stirring speed of 250 rpm.

For a dropping liquid (1), styrene (71 parts by mass) and acrylic acid (29 parts by mass) were mixed and diluted with PGMEA (60 parts by mass) to obtain the dropping liquid (1).

For a dropping liquid (2), V-601 (dimethyl 2,2′-azobis(2-methylpropionate), 9.637 parts by mass) was dissolved in PGMEA (136.56 parts by mass) to obtain the dropping liquid (2).

Next, the dropping liquid (1) and the dropping liquid (2) were simultaneously added dropwise to the 2,000 mL flask containing the above-described mixed solution heated to 90° C. over 3 hours. After the dropwise addition, V-601 (2.401 parts by mass) was added to the flask three times every hour. Thereafter, stirring was further carried out at 90° C. for 3 hours. Thereafter, the obtained reaction solution in the flask was diluted with PGMEA to obtain a solution containing the resin A-6 (concentration of solid contents: 36.3% by mass).
A-7: methacrylic resin, methyl methacrylate/dicyclopentanyl methacrylate/methacrylic acid=40% by mass/40% by mass/20% by mass, synthesized by the following method;

A solution containing the resin A-7 was synthesized in the same manner as in the resin A-6 described above, except that the dropping liquid (1) and the dropping liquid (2) were changed (concentration of solid contents: 36.3% by mass).

For the dropping liquid (1), methyl methacrylate (40 parts by mass), dicyclopentanyl methacrylate (40 parts by mass), and methacrylic acid (20 parts by mass) were mixed and diluted with PGMEA (60 parts) to obtain the dropping liquid (1).

For the dropping liquid (2), V-601 (dimethyl 2,2′-azobis(2-methylpropionate), 9.637 parts by mass) was dissolved in PGMEA (136.56 parts by mass) to obtain the dropping liquid (2).
A-8: liquid crystal polymer (liquid crystal polyester), synthesized by the following method;

435 g of p-hydroxybenzoic acid, 164 g of 4,4′-dihydroxybiphenyl, 44 g of hydroquinone, 146 g of terephthalic acid, 78 g of isophthalic acid, and 684 g of acetic anhydride were charged into a 2.5 L reaction container equipped with a stirring blade and a retention tube, and the mixture was reacted at 150° C. for 2.5 hours while stirring in a nitrogen gas atmosphere, and then the mixture was heated to 300° C. for 3.5 hours. Thereafter, the polymerization temperature was maintained at 300° C., the pressure was reduced to 1.0 mmHg in 1.0 hours, and the reaction was further continued for 2 hours. Next, the inside of the reaction container was pressurized to 0.12 MPa, and the resin was discharged in a strand-like form to obtain the resin A-8.
A-9: vinylbenzyl-modified polyphenylene ether resin, manufactured by MITSUBISHI GAS CHEMICAL COMPANY, INC., toluene solution of “OPE-2St 1200”
   [Filler X or comparative filler]

### <Filler X>

NHM-5N: silicon dioxide (spherical silica), surface-treated product, manufactured by TOKUYAMA CORPORATION
NHM-4N: silicon dioxide (spherical silica), surface-treated product, manufactured by TOKUYAMA CORPORATION
NHM-3N: silicon dioxide (spherical silica), surface-treated product, manufactured by TOKUYAMA CORPORATION
NHM-24D: silicon dioxide (spherical silica), surface-treated product, manufactured by TOKUYAMA CORPORATION
NP-5N: silicon dioxide (spherical silica), surface-treated product, manufactured by TOKUYAMA CORPORATION
NP-4N: silicon dioxide (spherical silica), surface-treated product, manufactured by TOKUYAMA CORPORATION
NP-3N: silicon dioxide (spherical silica), surface-treated product, manufactured by TOKUYAMA CORPORATION
NP-24D: silicon dioxide (spherical silica), surface-treated product, manufactured by TOKUYAMA CORPORATION
YA050C-MJE: silicon dioxide (spherical silica slurry), surface-treated product, concentration of solid contents: 50% by mass, MEK slurry, manufactured by Admatechs Co., Ltd.
Y50SP-AM1: silicon dioxide (spherical silica slurry), surface-treated product, manufactured by Admatechs Co., Ltd.
Y50SZ-AM1: silicon dioxide (spherical silica slurry), surface-treated product, manufactured by Admatechs Co., Ltd.
MEK-ST-ZL: silicon dioxide (spherical silica slurry), surface-treated product, manufactured by Nissan Chemical Corporation
MEK-ST-L: silicon dioxide (spherical silica slurry), surface-treated product, manufactured by Nissan Chemical Corporation
MEK-EC-2130Y: silicon dioxide (spherical silica slurry), surface-treated product, manufactured by Nissan Chemical Corporation

### <Comparative Filler>

SO-C2: silicon dioxide (spherical silica), un-surface-treated product, manufactured by Admatechs Co., Ltd.
Pre-adjusted product A: filler produced by the following method;

10 g of silica extracted from PGM-ST (silicon dioxide (spherical silica), un-surface-treated product, manufactured by Nissan Chemical Corporation) by centrifugal separation and filter, 39 g of NMP, and 1 g of 3-methacryloxypropyltrimethoxysilane were mixed with each other, and ultrasonic dispersion was carried out with stirring to produce the pre-adjusted product A.
PGM-ST: silicon dioxide (spherical silica), un-surface-treated product, manufactured by Nissan Chemical Corporation

### [Photopolymerization Initiator]

Oxe-01: Irgacure OXE-01, manufactured by BASF SE
Irg379: Irgacure (Omnirad) 379EG, manufactured by IGM Resins B.V.

### [Polymerizable Compound]

SR205NS: compound shown below, manufactured by Sartomer Inc.
SR209: compound shown below, manufactured by Sartomer Inc.
DPHA: dipentaerythritol hexaacrylate, manufactured by Tokyo Chemical Industry Co., Ltd.

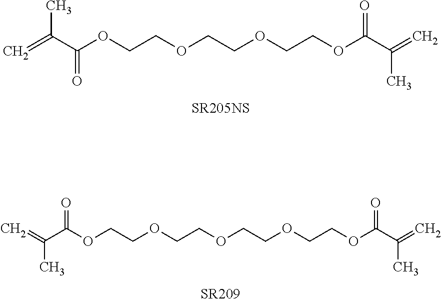

### [Surfactant]

S-506: silicone-based surfactant, manufactured by DIC Corporation
F-551A: MEGAFACE (registered trademark) F551A, fluorine-based surfactant, manufactured by DIC Corporation

### [Rust Inhibitor]

HAT: 5-amino-1H-tetrazole
ATA: 3-amino-1,2,4-triazole

### [Others]

HPC8000-65T: dicyclopentadiene-type diphenol compound (polycyclopentadiene-type diphenol compound) active ester curing agent, toluene solution having a concentration of solid contents of 65% by mass, manufactured by DIC Corporation
Silyl compound: synthesized by the following method;

700.0 g of 1,4-bis(dimethylsilyl)benzene (manufactured by Shin-Etsu Chemical Co., Ltd.) and 0.36 g of 5% by mass of platinum carbon powder (manufactured by N.E. Chemcat Corp.) were added to a 2 L four-neck flask equipped with a stirrer, a cooling pipe, a dropping funnel, and a thermometer, and heated to 90° C. using an oil bath. 149 g of trivinylphenylsilane (manufactured by Shin-Etsu Chemical Co., Ltd.) was added dropwise thereto. After the completion of the dropwise addition, the mixture was further stirred at 95° C. for 4 hours. After the completion of the stirring, the temperature was returned to 25° C., 8.4 g of activated carbon was added thereto, and the mixture was stirred for 2 hours. After the stirring, the mixture was filtered and concentrated under reduced pressure to obtain 500 g of a silyl compound.

The silyl compound was a mixture of compounds having structures represented by Formulae (a) to (e), and a proportion of each compound was (a):(b):(c):(d):(e)=29:21:16:9:25 (mol %). The structures represented by Formulae (a) to (e) are the same as structures described in paragraphs 0072 to 0076 of JP2020-026502A.

Components (a) to (e) are shown below.

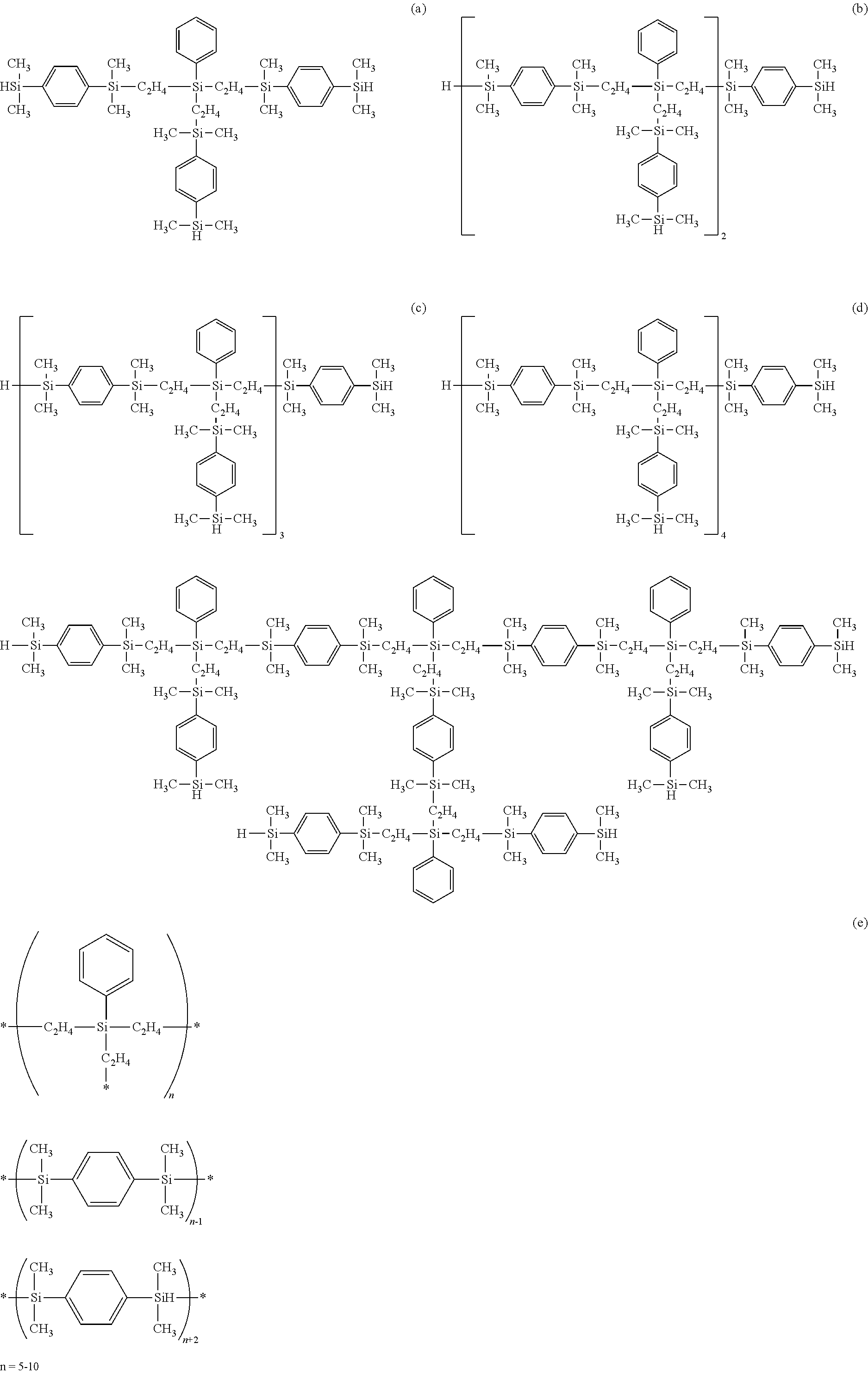

Platinum catalyst: hydrosilylation agent, diluted polysiloxane product of platinum 1,3-divinyl-1,1,3,3-tetramethyldisiloxane complex (content of platinum: 1% by mass)
MIR-500-60T: isopropyridene group-containing maleimide compound, toluene solution

### [Measurement of Average Particle Diameter]

Each of the compositions of each of Examples and Comparative Examples was applied onto a glass substrate, and dried to form a coating film having a thickness of 4.0 μm.

A cross section of the obtained coating film along a normal direction of the surface was cut out, the cross section was observed with a scanning electron microscope, and a major diameter of all fillers (the filler X or the comparative filler) observed in a region having a length of 3 μm in a longitudinal direction parallel to a thickness direction of the coating film and a length of 10 μm in a lateral direction orthogonal to the longitudinal direction was measured.

The above-described operation was performed at five different positions on the coating film, and an average value (arithmetic mean value) of the major diameters of all the fillers (the filler X and the comparative filler) measured in each operation was defined as the average particle diameter of the filler.

In the compositions of each of Examples and Comparative Examples, in a case where the average particle diameter was measured as described above, the coating film was heated at 220° C. for 5 hours, and then an average particle diameter was measured according to the same operation as described above, the average particle diameter was the same value as the average particle diameter before the heating treatment.

### [Content of Surface Modifier]

Each composition was applied onto a base material and dried (drying temperature: 100° C., drying time: 3 minutes) so that the thickness after drying was 10 μm, thereby forming a composition layer. Next, the obtained composition layer was dissolved in a mixed solvent of MEK:NMP=1:1. Thereafter, the obtained solution was centrifuged and filtered using a 0.2 μm filter to separate the filler (the filler X or the comparative filler). The obtained filler was dried (drying temperature: 100° C., drying time: 30 minutes) to obtain 30 mg of a filler for measurement. With the filler for measurement, a weight loss rate was measured three times under conditions of temperature rising (10° C./min) from room temperature to 1,000° C. in an air atmosphere using a TG-DTA device (TG/DTA7300) manufactured by Hitachi High-Tech Science Corporation, and a content (a value with respect to the total solid content of the composition) of the surface modifier was calculated from the arithmetic mean value thereof.

[Na⁺ content and Cl⁻ Content]

Each composition (1 g) was dissolved in acetone and then diluted with ultrapure water to prepare a solution of acetone:ultrapure water=1:9. A content (a value with respect to the total solid content of the composition) of Na⁺ and Cl⁻ in the supernatant of the solution was measured by ion chromatography. ICS-2100 manufactured by Thermo Fisher Scientific Inc. was used as an analysis apparatus; IonPac AS11HC manufactured by Thermo Fisher Scientific Inc. was used as a column in a case of Cl⁻, and IonPac CS12 manufactured by Thermo Fisher Scientific Inc. was used as a column in a case of Na⁺, and a column temperature was set to 35° C.

### [Various Measurements and Evaluations]

In a case where the composition contained a photopolymerization initiator, a measurement sample was produced according to the following method X.

Method X: a copper-clad polyimide film (METALOYAL, manufactured by Toray Industries, Inc.) was used as a base material, and the compositions shown in Table were applied to the base material and dried to obtain a laminate including a composition layer with a thickness of 10.0 μm on the base material. The obtained laminate was exposed (high pressure mercury lamp, integrated illuminance of 100 mJ/cm² measured with a 365 nm-wavelength illuminance meter) from a side of the composition layer opposite to the base material side, subjected to a heating treatment (220° C., 5 hours) in an oven, immersed in a 2 M hydrochloric acid for 8 hours for a peeling treatment, rinsed (with pure water at normal temperature for 1 hour), and then peeled off from the base material to obtain a self-supporting film derived from the composition layer. In a case where the self-supporting film could not be peeled off in the above-described peeling treatment, the film was further immersed in a 2 M hydrochloric acid for approximately 1 week and peeled off. The obtained self-supporting film was cut into strips to obtain a measurement sample.

In a case where the composition did not contain a photopolymerization initiator, a measurement sample was produced according to the following method Y.

Method Y: a copper-clad polyimide film (METALOYAL, manufactured by Toray Industries, Inc.) was used as a base material, and the compositions shown in Table were applied to the base material and dried to obtain a laminate including a composition layer with a thickness of 10.0 μm on the base material. The obtained laminate was subjected to a heating treatment (220° C., 5 hours) in an oven, immersed in a 2 M hydrochloric acid for 8 hours for a peeling treatment, rinsed (with pure water at normal temperature for 1 hour), and then peeled off from the base material to obtain a self-supporting film derived from the composition layer. In a case where the self-supporting film could not be peeled off in the above-described peeling treatment, the film was further immersed in a 2 M hydrochloric acid for approximately 1 week and peeled off. The obtained self-supporting film was cut into strips to obtain a measurement sample.

### [Dielectric Characteristics (Dielectric Loss)]

For the measurement sample obtained by the method X or the method Y, an average relative permittivity and an average dielectric loss tangent were measured using a 28 GHz split cylinder-type resonator (manufactured by Kanto Electronics Application & Development Inc.). Five samples were measured, and the maximum value and the minimum value thereof were excluded, and an arithmetic mean value of the remaining three values was used. Next, a dielectric loss Z was determined by the following expression, and dielectric characteristics were evaluated according to the following evaluation standard.

$$Dielectric loss Z = {( Dk \times Df )}^{1 / 2}$$

In the expression, Dk represents the measured average relative permittivity, and Df represents the measured average dielectric loss tangent.

### <Evaluation Standard for Dielectric Characteristics>

“A”: dielectric loss Z was 0.0025 or less.
“B”: dielectric loss Z was more than 0.0025 and 0.0050 or less.
“C”: dielectric loss Z was more than 0.0050.

### [Migration Resistance]

Each of the compositions was applied onto a copper pattern (line/space=3 μm/3 μm) having a thickness of 3.0 μm, which was formed as a wiring line in a comb shape on a silicon wafer base material, such that a thickness of the composition layer on the copper pattern was 10 μm, and dried to form a composition layer.

Next, in a case where the composition contained a photopolymerization initiator, the obtained composition layer was exposed using an ultra-high pressure mercury lamp. In this case, an integrated exposure amount measured with a 365 nm-wavelength illuminance meter was 100 mJ/cm². After the exposure, a heating treatment was performed at 220° C. for 300 minutes in a nitrogen atmosphere to produce a sample for evaluation.

In addition, in a case where the composition did not contain a photopolymerization initiator, the obtained composition layer was subjected to a heating treatment at 220° C. for 300 minutes in a nitrogen atmosphere to produce a sample for evaluation.

Ten samples for evaluation were produced, respectively, each sample for evaluation was installed in a chamber at 130° C. and 85% RH (relative humidity) using a high accelerated life test (HAST) machine, and whether or not migration occurred after 96 hours elapsed from the application of a voltage of 10 V was confirmed. In a sample for evaluation, in which the initial resistance value measured at room temperature (23° C.) was 1×10¹⁴Ω or more, it was assumed that the migration occurred at a time when the resistance value was 1×10³Ω or less.

### <Evaluation Standard for Migration Resistance>

“A”: number of measurement samples in which the migration occurred was 0 or 1.
“B”: number of measurement samples in which the migration occurred was 2 or 3.
“C”: number of measurement samples in which the migration occurred was 4 or 5.
“D”: number of measurement samples in which the migration occurred was 6 or 7.
“E”: number of measurement samples in which the migration occurred was 8 to 10.

Hereinafter, the content of various components and the evaluation results are shown.

The column of “Content in solid content” indicates a concentration of solid contents (% by mass) of the various components in the composition with respect to the total solid content.

The column of “Content of surface modifier” indicates a content (% by mass) of the surface modifier with respect to the total mass of the filler X.

The column of “Content of Na⁺ (ppm by mass)” indicates a content (ppm by mass) of the sodium ion with respect to the total solid content in the composition.

The column of “Content of Cl⁻ content (ppm by mass)” indicates a content (ppm by mass) of the chloride ion with respect to the total solid content in the composition.

TABLE 1

| | Composition | | | | | | | | | | | |
|---|---|---|---|---|---|---|---|---|---|---|---|---|
| | | | (B) Filler X or | | | | (C) Photopolymerization | | (D) Polymerizable | | | |
| | (A) Resin | | comparative filler | | | | initiator | | compound | | (E) Surfactant | |
| | | Content | | | | Content | | Content | | Content | | Content |
| | | (% by | | Particle | | (% by | | (% by | | (% by | | (% by |
| | Type | mass) | Type | diameter | | mass) | Type | mass) | Type | mass) | Type | mass) |
| Example 1 | A-1 | 30.0% | NHM-5N | 100 | nm | 70.0% | — | — | — | — | — | — |
| Example 2 | A-1 | 30.0% | NHM-4N | 120 | nm | 70.0% | — | — | — | — | — | — |
| Example 3 | A-1 | 30.0% | NHM-3N | 150 | nm | 70.0% | — | — | — | — | — | — |
| Example 4 | A-1 | 30.0% | NHM-24D | 240 | nm | 70.0% | — | — | — | — | — | — |
| Example 5 | A-1 | 30.0% | NP-5N | 100 | nm | 70.0% | — | — | — | — | — | — |
| Example 6 | A-1 | 30.0% | NP-4N | 120 | nm | 70.0% | — | — | — | — | — | — |
| Example 7 | A-1 | 30.0% | NP-3N | 150 | nm | 70.0% | — | — | — | — | — | — |
| Example 8 | A-1 | 30.0% | NP-24D | 240 | nm | 70.0% | — | — | — | — | — | — |
| Example 9 | A-1 | 30.0% | YA050C-MJE | 50 | nm | 70.0% | — | — | — | — | — | — |
| Example 10 | A-1 | 30.0% | Y50SP-AM1 | 50 | nm | 70.0% | — | — | — | — | — | — |
| Example 11 | A-1 | 30.0% | Y50SZ-AM1 | 50 | nm | 70.0% | — | — | — | — | — | — |
| Example 12 | A-1 | 30.0% | MEK-ST-ZL | 80 | nm | 70.0% | — | — | — | — | — | — |
| Example 13 | A-1 | 30.0% | MEK-ST-L | 45 | nm | 70.0% | — | — | — | — | — | — |
| Example 14 | A-1 | 30.0% | MEK-EC-2130Y | 12 | nm | 70.0% | — | — | — | — | — | — |
| Example 15 | A-1 | 50.0% | NHM-5N | 100 | nm | 50.0% | — | — | — | — | — | — |
| Example 16 | A-1 | 50.0% | NHM-4N | 120 | nm | 50.0% | — | — | — | — | — | — |
| Example 17 | A-1 | 50.0% | NHM-3N | 150 | nm | 50.0% | — | — | — | — | — | — |
| Example 18 | A-1 | 50.0% | NP-5N | 100 | nm | 50.0% | — | — | — | — | — | — |
| Example 19 | A-1 | 50.0% | NP-4N | 120 | nm | 50.0% | — | — | — | — | — | — |
| Example 20 | A-1 | 50.0% | NP-3N | 150 | nm | 50.0% | — | — | — | — | — | — |
| Example 21 | A-1 | 50.0% | YA050C-MJE | 50 | nm | 50.0% | — | — | — | — | — | — |
| Example 22 | A-1 | 39.0% | NHM-5N | 100 | nm | 50.0% | Oxe-01 | 1.0% | SR205NS | 10.0% | — | — |
| Example 23 | A-1 | 39.0% | NHM-4N | 120 | nm | 50.0% | Oxe-01 | 1.0% | SR205NS | 10.0% | — | — |
| Example 24 | A-1 | 39.0% | NHM-3N | 150 | nm | 50.0% | Oxe-01 | 1.0% | SR205NS | 10.0% | — | — |
| Example 25 | A-1 | 39.0% | NP-5N | 100 | nm | 50.0% | Irg379 | 1.0% | SR209 | 10.0% | — | — |
| Example 26 | A-1 | 39.0% | NP-4N | 120 | nm | 50.0% | Irg379 | 1.0% | SR209 | 10.0% | — | — |
| Example 27 | A-1 | 39.0% | NP-3N | 150 | nm | 50.0% | Irg379 | 1.0% | SR209 | 10.0% | — | — |
| Example 28 | A-1 | 39.0% | YA050C-MJE | 50 | nm | 50.0% | Irg379 | 1.0% | SR209 | 10.0% | — | — |
| Example 29 | A-1 | 49.0% | NHM-5N | 100 | nm | 50.0% | — | — | — | — | S-506 | 0.2% |
| Example 30 | A-1 | 49.0% | NHM-4N | 120 | nm | 50.0% | — | — | — | — | S-506 | 0.2% |

| | | | | | | | Measurement | | | | |
|---|---|---|---|---|---|---|---|---|---|---|---|
| | Composition | | | | | | Surface | | Content | | |
| | (F) Rust inhibitor | | (G) Others | | | | modifier | Content | of Cl⁻ | | |
| | | Content | | Content | | Content | Content | of Na⁺ | content | Evaluation | |
| | | (% by | | (% by | | (% by | (% by | (ppm by | (ppm by | Dielectric | Migration |
| | Type | mass) | Type | mass) | Type | mass) | mass) | mass | mass) | characteristics | resistance |
| Example 1 | — | — | — | — | — | — | 1.0% | 6 | 6 | A | A |
| Example 2 | — | — | — | — | — | — | 1.0% | 6 | 6 | A | A |
| Example 3 | — | — | — | — | — | — | 1.0% | 6 | 6 | A | A |
| Example 4 | — | — | — | — | — | — | 1.0% | 6 | 6 | A | B |
| Example 5 | — | — | — | — | — | — | 1.0% | 6 | 6 | A | A |
| Example 6 | — | — | — | — | — | — | 1.0% | 6 | 6 | A | A |
| Example 7 | — | — | — | — | — | — | 1.0% | 6 | 6 | A | A |
| Example 8 | — | — | — | — | — | — | 1.0% | 6 | 6 | A | B |
| Example 9 | — | — | — | — | — | — | 2.0% | 20 | 20 | B | A |
| Example 10 | — | — | — | — | — | — | 2.0% | 20 | 20 | B | A |
| Example 11 | — | — | — | — | — | — | 2.0% | 20 | 20 | B | A |
| Example 12 | — | — | — | — | — | — | 2.0% | 20 | 20 | B | A |
| Example 13 | — | — | — | — | — | — | 2.0% | 20 | 20 | B | A |
| Example 14 | — | — | — | — | — | — | 3.0% | 30 | 30 | B | C |
| Example 15 | — | — | — | — | — | — | 1.0% | 6 | 6 | A | A |
| Example 16 | — | — | — | — | — | — | 1.0% | 6 | 6 | A | A |
| Example 17 | — | — | — | — | — | — | 1.0% | 6 | 6 | A | A |
| Example 18 | — | — | — | — | — | — | 1.0% | 6 | 6 | A | A |
| Example 19 | — | — | — | — | — | — | 1.0% | 6 | 6 | A | A |
| Example 20 | — | — | — | — | — | — | 1.0% | 6 | 6 | A | A |
| Example 21 | — | — | — | — | — | — | 2.0% | 20 | 20 | B | A |
| Example 22 | — | — | — | — | — | — | 1.0% | 6 | 6 | A | A |
| Example 23 | — | — | — | — | — | — | 1.0% | 6 | 6 | A | A |
| Example 24 | — | — | — | — | — | — | 1.0% | 6 | 6 | A | A |
| Example 25 | — | — | — | — | — | — | 1.0% | 6 | 6 | A | A |
| Example 26 | — | — | — | — | — | — | 1.0% | 6 | 6 | A | A |
| Example 27 | — | — | — | — | — | — | 1.0% | 6 | 6 | A | A |
| Example 28 | — | — | — | — | — | — | 2.0% | 20 | 20 | B | A |
| Example 29 | HAT | 0.8% | — | — | — | — | 1.0% | 6 | 6 | A | A |
| Example 30 | HAT | 0.8% | — | — | — | — | 1.0% | 6 | 6 | A | A |

TABLE 2

| | Composition | | | | | | | | | | | |
|---|---|---|---|---|---|---|---|---|---|---|---|---|
| | | | (B) Filler X or | | | | (C) Photopolymerization | | (D) Polymerizable | | | |
| | (A) Resin | | comparative filler | | | | initiator | | compound | | (E) Surfactant | |
| | | Content | | | | Content | | Content | | Content | | Content |
| | | (% by | | Particle | | (% by | | (% by | | (% by | | (% by |
| | Type | mass) | Type | diameter | | mass) | Type | mass) | Type | mass) | Type | mass) |
| Example 31 | A-1 | 49.0% | NHM-3N | 150 | nm | 50.0% | — | — | — | — | S-506 | 0.2% |
| Example 32 | A-1 | 49.0% | NP-5N | 100 | nm | 50.0% | — | — | — | — | F-551A | 0.2% |
| Example 33 | A-1 | 49.0% | NP-4N | 120 | nm | 50.0% | — | — | — | — | F-551A | 0.2% |
| Example 34 | A-1 | 49.0% | NP-3N | 150 | nm | 50.0% | — | — | — | — | F-551A | 0.2% |
| Example 35 | A-1 | 49.0% | YA050C-MJE | 50 | nm | 50.0% | — | — | — | — | F-551A | 0.2% |
| Example 36 | A-2 | 15.0% | NHM-5N | 100 | nm | 70.0% | — | — | — | — | — | — |
| Example 37 | A-2 | 15.0% | NHM-4N | 120 | nm | 70.0% | — | — | — | — | — | — |
| Example 38 | A-2 | 15.0% | NHM-3N | 150 | nm | 70.0% | — | — | — | — | — | — |
| Example 39 | A-2 | 15.0% | NHM-24D | 240 | nm | 70.0% | — | — | — | — | — | — |
| Example 40 | A-2 | 15.0% | NP-5N | 100 | nm | 70.0% | — | — | — | — | — | — |
| Example 41 | A-2 | 15.0% | NP-4N | 120 | nm | 70.0% | — | — | — | — | — | — |
| Example 42 | A-2 | 15.0% | NP-3N | 150 | nm | 70.0% | — | — | — | — | — | — |
| Example 43 | A-2 | 15.0% | NP-24D | 240 | nm | 70.0% | — | — | — | — | — | — |
| Example 44 | A-2 | 15.0% | YA050C-MJE | 50 | nm | 70.0% | — | — | — | — | — | — |
| Example 45 | A-2 | 15.0% | Y50SP-AM1 | 50 | nm | 70.0% | — | — | — | — | — | — |
| Example 46 | A-2 | 15.0% | Y50SZ-AM1 | 50 | nm | 70.0% | — | — | — | — | — | — |
| Example 47 | A-2 | 15.0% | MEK-ST-ZL | 80 | nm | 70.0% | — | — | — | — | — | — |
| Example 48 | A-2 | 15.0% | MEK-ST-L | 45 | nm | 70.0% | — | — | — | — | — | — |
| Example 49 | A-2 | 15.0% | MEK-EC-2130Y | 12 | nm | 70.0% | — | — | — | — | — | — |

| | Composition | | | | | | Measurement | | | | |
|---|---|---|---|---|---|---|---|---|---|---|---|
| | | | | | | | Surface | | Content | | |
| | (F) Rust inhibitor | | (G) Others | | | | modifier | Content | of Cl⁻ | | |
| | | Content | | Content | | Content | Content | of Na⁺ | content | Evaluation | |
| | | (% by | | (% by | | (% by | (% by | (ppm by | (ppm by | Dielectric | Migration |
| | Type | mass) | Type | mass) | Type | mass) | mass) | mass | mass) | characteristics | resistance |
| Example 31 | HAT | 0.8% | — | — | — | — | 1.0% | 6 | 6 | A | A |
| Example 32 | ATA | 0.8% | — | — | — | — | 1.0% | 6 | 6 | A | A |
| Example 33 | ATA | 0.8% | — | — | — | — | 1.0% | 6 | 6 | A | A |
| Example 34 | ATA | 0.8% | — | — | — | — | 1.0% | 6 | 6 | A | A |
| Example 35 | ATA | 0.8% | — | — | — | — | 2.0% | 20 | 20 | B | A |
| Example 36 | — | — | HPC8000-65T | 15.0% | — | — | 1.0% | 6 | 6 | A | A |
| Example 37 | — | — | HPC8000-65T | 15.0% | — | — | 1.0% | 6 | 6 | A | A |
| Example 38 | — | — | HPC8000-65T | 15.0% | — | — | 1.0% | 6 | 6 | A | A |
| Example 39 | — | — | HPC8000-65T | 15.0% | — | — | 1.0% | 6 | 6 | A | B |
| Example 40 | — | — | HPC8000-65T | 15.0% | — | — | 1.0% | 6 | 6 | A | A |
| Example 41 | — | — | HPC8000-65T | 15.0% | — | — | 1.0% | 6 | 6 | A | A |
| Example 42 | — | — | HPC8000-65T | 15.0% | — | — | 1.0% | 6 | 6 | A | A |
| Example 43 | — | — | HPC8000-65T | 15.0% | — | — | 1.0% | 6 | 6 | A | B |
| Example 44 | — | — | HPC8000-65T | 15.0% | — | — | 2.0% | 20 | 20 | B | A |
| Example 45 | — | — | HPC8000-65T | 15.0% | — | — | 2.0% | 20 | 20 | B | A |
| Example 46 | — | — | HPC8000-65T | 15.0% | — | — | 2.0% | 20 | 20 | B | A |
| Example 47 | — | — | HPC8000-65T | 15.0% | — | — | 2.0% | 20 | 20 | B | A |
| Example 48 | — | — | HPC8000-65T | 15.0% | — | — | 2.0% | 20 | 20 | B | A |
| Example 49 | — | — | HPC8000-65T | 15.0% | — | — | 3.0% | 30 | 30 | B | C |

TABLE 3

| | Composition | | | | | | | | | | | |
|---|---|---|---|---|---|---|---|---|---|---|---|---|
| | | | (B) Filler X or | | | | (C) Photopolymerization | | (D) Polymerizable | | | |
| | (A) Resin | | comparative filler | | | | initiator | | compound | | (E) Surfactant | |
| | | Content | | | | Content | | Content | | Content | | Content |
| | | (% by | | Particle | | (% by | | (% by | | (% by | | (% by |
| | Type | mass) | Type | diameter | | mass) | Type | mass) | Type | mass) | Type | mass) |
| Example 50 | A-2 | 9.0% | NHM-5N | 100 | nm | 70.0% | Oxe-01 | 1.0% | DPHA | 10.0% | — | — |
| Example 51 | A-2 | 9.0% | NHM-4N | 120 | nm | 70.0% | Oxe-01 | 1.0% | DPHA | 10.0% | — | — |
| Example 52 | A-2 | 9.0% | NHM-3N | 150 | nm | 70.0% | Oxe-01 | 1.0% | DPHA | 10.0% | — | — |
| Example 53 | A-2 | 9.0% | NP-5N | 100 | nm | 70.0% | Irg379 | 1.0% | SR205NS | 10.0% | — | — |
| Example 54 | A-2 | 9.0% | NP-4N | 120 | nm | 70.0% | Irg379 | 1.0% | SR205NS | 10.0% | — | — |
| Example 55 | A-2 | 9.0% | NP-3N | 150 | nm | 70.0% | Irg379 | 1.0% | SR205NS | 10.0% | — | — |
| Example 56 | A-2 | 9.0% | YA050C-MJE | 50 | nm | 70.0% | Irg379 | 1.0% | SR205NS | 10.0% | — | — |
| Example 57 | A-2 | 9.0% | NHM-5N | 100 | nm | 70.0% | Oxe-01 | 1.0% | DPHA | 10.0% | S-506 | 0.2% |
| Example 58 | A-2 | 9.0% | NHM-4N | 120 | nm | 70.0% | Oxe-01 | 1.0% | DPHA | 10.0% | S-506 | 0.2% |
| Example 59 | A-2 | 9.0% | NHM-3N | 150 | nm | 70.0% | Oxe-01 | 1.0% | DPHA | 10.0% | S-506 | 0.2% |
| Example 60 | A-2 | 9.0% | NP-5N | 100 | nm | 70.0% | Oxe-01 | 1.0% | DPHA | 10.0% | F-551A | 0.2% |
| Example 61 | A-2 | 9.0% | NP-4N | 120 | nm | 70.0% | Oxe-01 | 1.0% | DPHA | 10.0% | F-551A | 0.2% |
| Example 62 | A-2 | 9.0% | NP-3N | 150 | nm | 70.0% | Oxe-01 | 1.0% | DPHA | 10.0% | F-551A | 0.2% |
| Example 63 | A-2 | 9.0% | YA050C-MJE | 50 | nm | 70.0% | Oxe-01 | 1.0% | DPHA | 10.0% | F-551A | 0.2% |
| Example 64 | A-3 | 40.0% | NHM-5N | 100 | nm | 60.0% | — | — | — | — | — | — |
| Example 65 | A-3 | 40.0% | NHM-4N | 120 | nm | 60.0% | — | — | — | — | — | — |
| Example 66 | A-3 | 40.0% | NHM-3N | 150 | nm | 60.0% | — | — | — | — | — | — |
| Example 67 | A-3 | 40.0% | NHM-24D | 240 | nm | 60.0% | — | — | — | — | — | — |
| Example 68 | A-3 | 40.0% | NP-5N | 100 | nm | 60.0% | — | — | — | — | — | — |
| Example 69 | A-3 | 40.0% | NP-4N | 120 | nm | 60.0% | — | — | — | — | — | — |
| Example 70 | A-3 | 40.0% | NP-3N | 150 | nm | 60.0% | — | — | — | — | — | — |
| Example 71 | A-3 | 40.0% | NP-24D | 240 | nm | 60.0% | — | — | — | — | — | — |

| | Composition | | | | | | Measurement | | | | |
|---|---|---|---|---|---|---|---|---|---|---|---|
| | | | | | | | Surface | | Content | | |
| | (F) Rust inhibitor | | (G) Others | | | | modifier | Content | of Cl⁻ | | |
| | | Content | | Content | | Content | Content | of Na⁺ | content | Evaluation | |
| | | (% by | | (% by | | (% by | (% by | (ppm by | (ppm by | Dielectric | Migration |
| | Type | mass) | Type | mass) | Type | mass) | mass) | mass | mass) | characteristics | resistance |
| Example 50 | — | — | HPC8000-65T | 10.0% | — | — | 1.0% | 6 | 6 | A | A |
| Example 51 | — | — | HPC8000-65T | 10.0% | — | — | 1.0% | 6 | 6 | A | A |
| Example 52 | — | — | HPC8000-65T | 10.0% | — | — | 1.0% | 6 | 6 | A | A |
| Example 53 | — | — | HPC8000-65T | 10.0% | — | — | 1.0% | 6 | 6 | A | A |
| Example 54 | — | — | HPC8000-65T | 10.0% | — | — | 1.0% | 6 | 6 | A | A |
| Example 55 | — | — | HPC8000-65T | 10.0% | — | — | 1.0% | 6 | 6 | A | A |
| Example 56 | — | — | HPC8000-65T | 10.0% | — | — | 2.0% | 20 | 20 | B | A |
| Example 57 | HAT | 0.8% | HPC8000-65T | 9.0% | — | — | 1.0% | 6 | 6 | A | A |
| Example 58 | HAT | 0.8% | HPC8000-65T | 9.0% | — | — | 1.0% | 6 | 6 | A | A |
| Example 59 | HAT | 0.8% | HPC8000-65T | 9.0% | — | — | 1.0% | 6 | 6 | A | A |
| Example 60 | ATA | 0.8% | HPC8000-65T | 9.0% | — | — | 1.0% | 6 | 6 | A | A |
| Example 61 | ATA | 0.8% | HPC8000-65T | 9.0% | — | — | 1.0% | 6 | 6 | A | A |
| Example 62 | ATA | 0.8% | HPC8000-65T | 9.0% | — | — | 1.0% | 6 | 6 | A | A |
| Example 63 | ATA | 0.8% | HPC8000-65T | 9.0% | — | — | 2.0% | 20 | 20 | B | A |
| Example 64 | — | — | — | — | — | — | 1.0% | 6 | 6 | A | A |
| Example 65 | — | — | — | — | — | — | 1.0% | 6 | 6 | A | A |
| Example 66 | — | — | — | — | — | — | 1.0% | 6 | 6 | A | A |
| Example 67 | — | — | — | — | — | — | 1.0% | 6 | 6 | A | B |
| Example 68 | — | — | — | — | — | — | 1.0% | 6 | 6 | A | A |
| Example 69 | — | — | — | — | — | — | 1.0% | 6 | 6 | A | A |
| Example 70 | — | — | — | — | — | — | 1.0% | 6 | 6 | A | A |
| Example 71 | — | — | — | — | — | — | 1.0% | 6 | 6 | A | B |

TABLE 4

| | Composition | | | | | | | | | | |
|---|---|---|---|---|---|---|---|---|---|---|---|
| | | | (B) Filler X or | | | (C) Photopolymerization | | (D) Polymerizable | | | |
| | (A) Resin | | comparative filler | | | initiator | | compound | | (E) Surfactant | |
| | | Content | | | Content | | Content | | Content | | Content |
| | | (% by | | Particle | (% by | | (% by | | (% by | | (% by |
| | Type | mass) | Type | diameter | mass) | Type | mass) | Type | mass) | Type | mass) |
| Example 72 | A-3 | 19.0% | NHM-5N | 100 nm | 70.0% | Oxe-01 | 1.0% | DPHA | 10.0% | — | — |
| Example 73 | A-3 | 19.0% | NHM-4N | 120 nm | 70.0% | Oxe-01 | 1.0% | DPHA | 10.0% | — | — |
| Example 74 | A-3 | 19.0% | NHM-3N | 150 nm | 70.0% | Oxe-01 | 1.0% | DPHA | 10.0% | — | — |
| Example 75 | A-3 | 19.0% | NP-5N | 100 nm | 70.0% | Irg379 | 1.0% | SR205NS | 10.0% | — | — |
| Example 76 | A-3 | 19.0% | NP-4N | 120 nm | 70.0% | Irg379 | 1.0% | SR205NS | 10.0% | — | — |
| Example 77 | A-3 | 19.0% | NP-3N | 150 nm | 70.0% | Irg379 | 1.0% | SR205NS | 10.0% | — | — |
| Example 78 | A-3 | 29.0% | NHM-5N | 100 nm | 70.0% | — | — | — | — | S-506 | 0.2% |
| Example 79 | A-3 | 29.0% | NHM-4N | 120 nm | 70.0% | — | — | — | — | S-506 | 0.2% |
| Example 80 | A-3 | 29.0% | NHM-3N | 150 nm | 70.0% | — | — | — | — | S-506 | 0.2% |
| Example 81 | A-3 | 29.0% | NP-5N | 100 nm | 70.0% | — | — | — | — | F-551A | 0.2% |
| Example 82 | A-3 | 29.0% | NP-4N | 120 nm | 70.0% | — | — | — | — | F-551A | 0.2% |
| Example 83 | A-3 | 29.0% | NP-3N | 150 nm | 70.0% | — | — | — | — | F-551A | 0.2% |
| Example 84 | A-4 | 15.0% | NHM-5N | 100 nm | 60.0% | — | — | — | — | — | — |
| Example 85 | A-4 | 15.0% | NHM-4N | 120 nm | 60.0% | — | — | — | — | — | — |
| Example 86 | A-4 | 15.0% | NHM-3N | 150 nm | 60.0% | — | — | — | — | — | — |
| Example 87 | A-4 | 15.0% | NHM-24D | 240 nm | 60.0% | — | — | — | — | — | — |
| Example 88 | A-4 | 15.0% | NP-5N | 100 nm | 60.0% | — | — | — | — | — | — |
| Example 89 | A-4 | 15.0% | NP-4N | 120 nm | 60.0% | — | — | — | — | — | — |
| Example 90 | A-4 | 15.0% | NP-3N | 150 nm | 60.0% | — | — | — | — | — | — |
| Example 91 | A-4 | 15.0% | NP-24D | 240 nm | 60.0% | — | — | — | — | — | — |
| Example 92 | A-4 | 12.0% | NHM-5N | 100 nm | 60.0% | Oxe-01 | 1.0% | DPHA | 9.0% | — | — |
| Example 93 | A-4 | 12.0% | NHM-4N | 120 nm | 60.0% | Oxe-01 | 1.0% | DPHA | 9.0% | — | — |
| Example 94 | A-4 | 12.0% | NHM-3N | 150 nm | 60.0% | Oxe-01 | 1.0% | DPHA | 9.0% | — | — |
| Example 95 | A-4 | 12.0% | NP-5N | 100 nm | 60.0% | Irg379 | 1.0% | SR20SNS | 9.0% | — | — |
| Example 96 | A-4 | 12.0% | NP-4N | 120 nm | 60.0% | Irg379 | 1.0% | SR205NS | 9.0% | — | — |
| Example 97 | A-4 | 12.0% | NP-3N | 150 nm | 60.0% | Irg379 | 1.0% | SR205NS | 9.0% | — | — |

| | | | | | | | Measurement | | | | |
|---|---|---|---|---|---|---|---|---|---|---|---|
| | Composition | | | | | | Surface | | Content | | |
| | (F) Rust inhibitor | | (G) Others | | | | modifier | Content | of Cl⁻ | | |
| | | Content | | Content | | Content | Content | of Na⁺ | content | Evaluation | |
| | | (% by | | (% by | | (% by | (% by | (ppm by | (ppm by | Dielectric | Migration |
| | Type | mass) | Type | mass) | Type | mass) | mass) | mass | mass) | characteristics | resistance |
| Example 72 | — | — | — | — | — | — | 1.0% | 6 | 6 | A | A |
| Example 73 | — | — | — | — | — | — | 1.0% | 6 | 6 | A | A |
| Example 74 | — | — | — | — | — | — | 1.0% | 6 | 6 | A | A |
| Example 75 | — | — | — | — | — | — | 1.0% | 6 | 6 | A | A |
| Example 76 | — | — | — | — | — | — | 1.0% | 6 | 6 | A | A |
| Example 77 | — | — | — | — | — | — | 1.0% | 6 | 6 | A | A |
| Example 78 | HAT | 0.8% | — | — | — | — | 1.0% | 6 | 6 | A | A |
| Example 79 | HAT | 0.8% | — | — | — | — | 1.0% | 6 | 6 | A | A |
| Example 80 | HAT | 0.8% | — | — | — | — | 1.0% | 6 | 6 | A | A |
| Example 81 | ATA | 0.8% | — | — | — | — | 1.0% | 6 | 6 | A | A |
| Example 82 | ATA | 0.8% | — | — | — | — | 1.0% | 6 | 6 | A | A |
| Example 83 | ATA | 0.8% | — | — | — | — | 1.0% | 6 | 6 | A | A |
| Example 84 | — | — | | 24% | | 1% | 1.0% | 6 | 6 | A | A |
| Example 85 | — | — | | 24% | | 1% | 1.0% | 6 | 6 | A | A |
| Example 86 | — | — | | 24% | | 1% | 1.0% | 6 | 6 | A | A |
| Example 87 | — | — | | 24% | | 1% | 1.0% | 6 | 6 | A | B |
| Example 88 | — | — | | 24% | | 1% | 1.0% | 6 | 6 | A | A |
| Example 89 | — | — | | 24% | | 1% | 1.0% | 6 | 6 | A | A |
| Example 90 | — | — | | 24% | | 1% | 1.0% | 6 | 6 | A | A |
| Example 91 | — | — | | 24% | | 1% | 1.0% | 6 | 6 | A | B |
| Example 92 | — | — | | 17% | | 1% | 1.0% | 6 | 6 | A | A |
| Example 93 | — | — | | 17% | | 1% | 1.0% | 6 | 6 | A | A |
| Example 94 | — | — | | 17% | | 1% | 1.0% | 6 | 6 | A | A |
| Example 95 | — | — | | 17% | | 1% | 1.0% | 6 | 6 | A | A |
| Example 96 | — | — | | 17% | | 1% | 1.0% | 6 | 6 | A | A |
| Example 97 | — | — | | 17% | | 1% | 1.0% | 6 | 6 | A | A |

TABLE 5

| | Composition | | | | | | | | | | |
|---|---|---|---|---|---|---|---|---|---|---|---|
| | | | (B) Filler X or | | | (C) Photopolymerization | | (D) Polymerizable | | | |
| | (A) Resin | | comparative filler | | | initiator | | compound | | (E) Surfactant | |
| | | Content | | | Content | | Content | | Content | | Content |
| | | (% by | | Particle | (% by | | (% by | | (% by | | (% by |
| | Type | mass) | Type | diameter | mass) | Type | mass) | Type | mass) | Type | mass) |
| Example 98 | A-5 | 40.0% | NHM-5N | 100 nm | 60.0% | | | | | | |
| Example 99 | A-5 | 40.0% | NHM-4N | 120 nm | 60.0% | | | | | | |
| Example 100 | A-5 | 40.0% | NHM-3N | 150 nm | 60.0% | | | | | | |
| Example 101 | A-5 | 40.0% | NHM-24D | 240 nm | 60.0% | | | | | | |
| Example 102 | A-5 | 40.0% | NP-5N | 100 nm | 60.0% | | | | | | |
| Example 103 | A-5 | 40.0% | NP-4N | 120 nm | 60.0% | | | | | | |
| Example 104 | A-5 | 40.0% | NP-3N | 150 nm | 60.0% | | | | | | |
| Example 105 | A-5 | 40.0% | NP-24D | 240 nm | 60.0% | | | | | | |
| Example 106 | A-5 | 29.0% | NHM-5N | 100 nm | 60.0% | Oxe-01 | 1.0% | DPHA | 10.0% | | |
| Example 107 | A-5 | 29.0% | NHM-4N | 120 nm | 60.0% | Oxe-01 | 1.0% | DPHA | 10.0% | | |
| Example 108 | A-5 | 29.0% | NHM-3N | 150 nm | 60.0% | Oxe-01 | 1.0% | DPHA | 10.0% | | |
| Example 109 | A-5 | 29.0% | NP-5N | 100 nm | 60.0% | Irg379 | 1.0% | SR205NS | 10.0% | | |
| Example 110 | A-5 | 29.0% | NP-4N | 120 nm | 60.0% | Irg379 | 1.0% | SR205NS | 10.0% | | |
| Example 111 | A-5 | 29.0% | NP-3N | 150 nm | 60.0% | Irg379 | 1.0% | SR205NS | 10.0% | | |
| Example 112 | A-6 | 30.0% | NHM-5N | 100 nm | 70.0% | | | | | | |
| Example 113 | A-6 | 30.0% | NHM-4N | 120 nm | 70.0% | | | | | | |
| Example 114 | A-6 | 30.0% | NHM-3N | 150 nm | 70.0% | | | | | | |
| Example 115 | A-6 | 30.0% | NHM-24D | 240 nm | 70.0% | | | | | | |
| Example 116 | A-6 | 30.0% | NP-5N | 100 nm | 70.0% | | | | | | |
| Example 117 | A-6 | 30.0% | NP-4N | 120 nm | 70.0% | | | | | | |
| Example 118 | A-6 | 30.0% | NP-3N | 150 nm | 70.0% | | | | | | |
| Example 119 | A-6 | 30.0% | NP-24D | 240 nm | 70.0% | | | | | | |
| Example 120 | A-6 | 19.0% | NHM-5N | 100 nm | 70.0% | Oxe-01 | 1.0% | DPHA | 10.0% | | |
| Example 121 | A-6 | 19.0% | NHM-4N | 120 nm | 70.0% | Oxe-01 | 1.0% | DPHA | 10.0% | | |
| Example 122 | A-6 | 19.0% | NHM-3N | 150 nm | 70.0% | Oxe-01 | 1.0% | DPHA | 10.0% | | |
| Example 123 | A-6 | 19.0% | NP-5N | 100 nm | 70.0% | Irg379 | 1.0% | SR205NS | 10.0% | | |
| Example 124 | A-6 | 19.0% | NP-4N | 120 nm | 70.0% | Irg379 | 1.0% | SR205NS | 10.0% | | |
| Example 125 | A-6 | 19.0% | NP-3N | 150 nm | 70.0% | Irg379 | 1.0% | SR205NS | 10.0% | | |

| | Composition | | | | | | Measurement | | | | |
|---|---|---|---|---|---|---|---|---|---|---|---|
| | | | | | | | Surface | | Content | | |
| | (F) Rust inhibitor | | (G) Others | | | | modifier | Content | of Cl⁻ | | |
| | | Content | | Content | | Content | Content | of Na⁺ | content | Evaluation | |
| | | (% by | | (% by | | (% by | (% by | (ppm by | (ppm by | Dielectric | Migration |
| | Type | mass) | Type | mass) | Type | mass) | mass) | mass | mass) | characteristics | resistance |
| Example 98 | | | | | | | 1.0% | 6 | 6 | A | A |
| Example 99 | | | | | | | 1.0% | 6 | 6 | A | A |
| Example 100 | | | | | | | 1.0% | 6 | 6 | A | A |
| Example 101 | | | | | | | 1.0% | 6 | 6 | A | B |
| Example 102 | | | | | | | 1.0% | 6 | 6 | A | A |
| Example 103 | | | | | | | 1.0% | 6 | 6 | A | A |
| Example 104 | | | | | | | 1.0% | 6 | 6 | A | A |
| Example 105 | | | | | | | 1.0% | 6 | 6 | A | B |
| Example 106 | | | | | | | 1.0% | 6 | 6 | A | A |
| Example 107 | | | | | | | 1.0% | 6 | 6 | A | A |
| Example 108 | | | | | | | 1.0% | 6 | 6 | A | A |
| Example 109 | | | | | | | 1.0% | 6 | 6 | A | A |
| Example 110 | | | | | | | 1.0% | 6 | 6 | A | A |
| Example 111 | | | | | | | 1.0% | 6 | 6 | A | A |
| Example 112 | | | | | | | 1.0% | 6 | 6 | A | A |
| Example 113 | | | | | | | 1.0% | 6 | 6 | A | A |
| Example 114 | | | | | | | 1.0% | 6 | 6 | A | A |
| Example 115 | | | | | | | 1.0% | 6 | 6 | A | B |
| Example 116 | | | | | | | 1.0% | 6 | 6 | A | A |
| Example 117 | | | | | | | 1.0% | 6 | 6 | A | A |
| Example 118 | | | | | | | 1.0% | 6 | 6 | A | A |
| Example 119 | | | | | | | 1.0% | 6 | 6 | A | B |
| Example 120 | | | | | | | 1.0% | 6 | 6 | A | A |
| Example 121 | | | | | | | 1.0% | 6 | 6 | A | A |
| Example 122 | | | | | | | 1.0% | 6 | 6 | A | A |
| Example 123 | | | | | | | 1.0% | 6 | 6 | A | A |
| Example 124 | | | | | | | 1.0% | 6 | 6 | A | A |
| Example 125 | | | | | | | 1.0% | 6 | 6 | A | A |

TABLE 6

| | Composition | | | | | | | | | | |
|---|---|---|---|---|---|---|---|---|---|---|---|
| | | | (B) Filler X or | | | (C) Photopolymerization | | (D) Polymerizable | | | |
| | (A) Resin | | comparative filler | | | initiator | | compound | | (E) Surfactant | |
| | | Content | | | Content | | Content | | Content | | Content |
| | | (% by | | Particle | (% by | | (% by | | (% by | | (% by |
| | Type | mass) | Type | diameter | mass) | Type | mass) | Type | mass) | Type | mass) |
| Example 126 | A-7 | 30.0% | NHM-5N | 100 nm | 70.0% | — | — | — | — | — | — |
| Example 127 | A-7 | 30.0% | NHM-4N | 120 nm | 70.0% | — | — | — | — | — | — |
| Example 128 | A-7 | 30.0% | NHM-3N | 150 nm | 70.0% | — | — | — | — | — | — |
| Example 129 | A-7 | 30.0% | NHM-24D | 240 nm | 70.0% | — | — | — | — | — | — |
| Example 130 | A-7 | 30.0% | NP-5N | 100 nm | 70.0% | — | — | — | — | — | — |
| Example 131 | A-7 | 30.0% | NP-4N | 120 nm | 70.0% | — | — | — | — | — | — |
| Example 132 | A-7 | 30.0% | NP-3N | 150 nm | 70.0% | — | — | — | — | — | — |
| Example 133 | A-7 | 30.0% | NP-24D | 240 nm | 70.0% | — | — | — | — | — | — |
| Example 134 | A-7 | 19.0% | NHM-5N | 100 nm | 70.0% | Oxe-01 | 1.0% | DPHA | 10.0% | — | — |
| Example 135 | A-7 | 19.0% | NHM-4N | 120 nm | 70.0% | Oxe-01 | 1.0% | DPHA | 10.0% | — | — |
| Example 136 | A-7 | 19.0% | NHM-3N | 150 nm | 70.0% | Oxe-01 | 1.0% | DPHA | 10.0% | — | — |
| Example 137 | A-7 | 19.0% | NP-5N | 100 nm | 70.0% | Irg379 | 1.0% | 5R205NS | 10.0% | — | — |
| Example 138 | A-7 | 19.0% | NP-4N | 120 nm | 70.0% | Irg379 | 1.0% | SR205NS | 10.0% | — | — |
| Example 139 | A-7 | 19.0% | NP-3N | 150 nm | 70.0% | Irg379 | 1.0% | SR205NS | 10.0% | — | — |
| Example 140 | A-8 | 30.0% | NHM-5N | 100 nm | 70.0% | — | — | — | — | — | — |
| Example 141 | A-8 | 30.0% | NHM-4N | 120 nm | 70.0% | — | — | — | — | — | — |
| Example 142 | A-8 | 30.0% | NHM-3N | 150 nm | 70.0% | — | — | — | — | — | — |
| Example 143 | A-8 | 30.0% | NHM-24D | 240 nm | 70.0% | — | — | — | — | — | — |
| Example 144 | A-8 | 30.0% | NP-5N | 100 nm | 70.0% | — | — | — | — | — | — |
| Example 145 | A-8 | 30.0% | NP-4N | 120 nm | 70.0% | — | — | — | — | — | — |
| Example 146 | A-8 | 30.0% | NP-3N | 150 nm | 70.0% | — | — | — | — | — | — |
| Example 147 | A-8 | 30.0% | NP-24D | 240 nm | 70.0% | — | — | — | — | — | — |
| Example 148 | A-8 | 29.0% | NHM-5N | 100 nm | 60.0% | Oxe-01 | 1.0% | DPHA | 10.0% | — | — |
| Example 149 | A-8 | 29.0% | NHM-4N | 120 nm | 60.0% | Oxe-01 | 1.0% | DPHA | 10.0% | — | — |
| Example 150 | A-8 | 29.0% | NHM-3N | 150 nm | 60.0% | Oxe-01 | 1.0% | DPHA | 10.0% | — | — |
| Example 151 | A-8 | 29.0% | NP-5N | 100 nm | 60.0% | Irg379 | 1.0% | SR205NS | 10.0% | — | — |
| Example 152 | A-8 | 29.0% | NP-4N | 120 nm | 60.0% | Irg379 | 1.0% | SR205NS | 10,0% | — | — |
| Example 153 | A-8 | 29.0% | NP-3N | 150 nm | 60.0% | Irg379 | 1.0% | SR205NS | 10.0% | — | — |

| | Composition | | | | | | Measurement | | | | |
|---|---|---|---|---|---|---|---|---|---|---|---|
| | | | | | | | Surface | | Content | | |
| | (F) Rust inhibitor | | (G) Others | | | | modifier | Content | of Cl⁻ | | |
| | | Content | | Content | | Content | Content | of Na⁺ | content | Evaluation | |
| | | (% by | | (% by | | (% by | (% by | (ppm by | (ppm by | Dielectric | Migration |
| | Type | mass) | Type | mass) | Type | mass) | mass) | mass | mass) | characteristics | resistance |
| Example 126 | — | — | — | — | — | — | 1.0% | 6 | 6 | A | A |
| Example 127 | — | — | — | — | — | — | 1.0% | 6 | 6 | A | A |
| Example 128 | — | — | — | — | — | — | 1.0% | 6 | 6 | A | A |
| Example 129 | — | — | — | — | — | — | 1.0% | 6 | 6 | A | B |
| Example 130 | — | — | — | — | — | — | 1.0% | 6 | 6 | A | A |
| Example 131 | — | — | — | — | — | — | 1.0% | 6 | 6 | A | A |
| Example 132 | — | — | — | — | — | — | 1.0% | 6 | 6 | A | A |
| Example 133 | — | — | — | — | — | — | 1.0% | 6 | 6 | A | B |
| Example 134 | — | — | — | — | — | — | 1.0% | 6 | 6 | A | A |
| Example 135 | — | — | — | — | — | — | 1.0% | 6 | 6 | A | A |
| Example 136 | — | — | — | — | — | — | 1.0% | 6 | 6 | A | A |
| Example 137 | — | — | — | — | — | — | 1.0% | 6 | 6 | A | A |
| Example 138 | — | — | — | — | — | — | 1.0% | 6 | 6 | A | A |
| Example 139 | — | — | — | — | — | — | 1.0% | 6 | 6 | A | A |
| Example 140 | — | — | — | — | — | — | 1.0% | 6 | 6 | A | A |
| Example 141 | — | — | — | — | — | — | 1.0% | 6 | 6 | A | A |
| Example 142 | — | — | — | — | — | — | 1.0% | 6 | 6 | A | A |
| Example 143 | — | — | — | — | — | — | 1.0% | 6 | 6 | A | B |
| Example 144 | — | — | — | — | — | — | 1.0% | 6 | 6 | A | A |
| Example 145 | — | — | — | — | — | — | 1.0% | 6 | 6 | A | A |
| Example 146 | — | — | — | — | — | — | 1.0% | 6 | 6 | A | A |
| Example 147 | — | — | — | — | — | — | 1.0% | 6 | 6 | A | B |
| Example 148 | — | — | — | — | — | — | 1.0% | 6 | 6 | A | A |
| Example 149 | — | — | — | — | — | — | 1.0% | 6 | 6 | A | A |
| Example 150 | — | — | — | — | — | — | 1.0% | 6 | 6 | A | A |
| Example 151 | — | — | — | — | — | — | 1.0% | 6 | 6 | A | A |
| Example 152 | — | — | — | — | — | — | 1.0% | 6 | 6 | A | A |
| Example 153 | — | — | — | — | — | — | 1.0% | 6 | 6 | A | A |

TABLE 7

| | Composition | | | | | | | | | | | |
|---|---|---|---|---|---|---|---|---|---|---|---|---|
| | | | (B) Filler X or | | | | (C) Photopolymerization | | (D) Polymerizable | | | |
| | (A) Resin | | comparative filler | | | | initiator | | compound | | (E) Surfactant | |
| | | Content | | | | Content | | Content | | Content | | Content |
| | | (% by | | Particle | | (% by | | (% by | | (% by | | (% by |
| | Type | mass) | Type | diameter | | mass) | Type | mass) | Type | mass) | Type | mass) |
| Example 154 | A-9 | 15.0% | NHM-5N | 100 | nm | 70.0% | — | — | — | — | — | — |
| Example 155 | A-9 | 15.0% | NHM-4N | 120 | nm | 70.0% | — | — | — | — | — | — |
| Example 156 | A-9 | 15.0% | NHM-3N | 150 | nm | 70.0% | — | — | — | — | — | — |
| Example 157 | A-9 | 15.0% | MHM-24D | 240 | nm | 70.0% | — | — | — | — | — | — |
| Example 158 | A-9 | 15.0% | NP-5N | 100 | nm | 70.0% | — | — | — | — | — | — |
| Example 159 | A-9 | 15.0% | NP-4N | 120 | nm | 70.0% | — | — | — | — | — | — |
| Example 160 | A-9 | 15.0% | NP-3N | 150 | nm | 70.0% | — | — | — | — | — | — |
| Example 161 | A-9 | 15.0% | NP-24D | 240 | nm | 70.0% | — | — | — | — | — | — |
| Example 162 | A-9 | 14.0% | NHM-5N | 100 | nm | 60.0% | Oxe-01 | 1.0% | DPHA | 10.0% | — | — |
| Example 163 | A-9 | 14.0% | NHM-4N | 120 | nm | 60.0% | Oxe-01 | 1.0% | DPHA | 10.0% | — | — |
| Example 164 | A-9 | 14.0% | NHM-3N | 150 | nm | 60.0% | Oxe-01 | 1.0% | DPHA | 10.0% | — | — |
| Example 165 | A-9 | 14.0% | NP-5N | 100 | nm | 60.0% | Irg379 | 1.0% | SR205NS | 10.0% | — | — |
| Example 166 | A-9 | 14.0% | NP-4N | 120 | nm | 60.0% | Irg379 | 1.0% | SR205NS | 10.0% | — | — |
| Example 167 | A-9 | 14.0% | NP-3N | 150 | nm | 60.0% | Irg379 | 1.0% | SR205NS | 10.0% | — | — |
| Comparative | A-1 | 50.0% | SO-C2 | 500 | nm | 50.0% | — | — | — | — | — | — |
| Example 1 | | | | | | | | | | | | |
| Comparative | A-1 | 50.0% | Pre-adjusted | 12 | nm | 50.0% | — | — | — | — | — | — |
| Example 2 | | | product A | | | | | | | | | |
| Comparative | A-1 | 50.0% | PGM-ST | 12 | nm | 50.0% | — | — | — | — | — | — |
| Example 3 | | | | | | | | | | | | |
| Comparative | A-1 | 60.0% | MEK-EC-2130Y | 12 | nm | 40.0% | — | — | — | — | — | — |
| Example 4 | | | | | | | | | | | | |

| | Composition | | | | | | Measurement | | | | |
|---|---|---|---|---|---|---|---|---|---|---|---|
| | | | | | | | Surface | | Content | | |
| | (F) Rust inhibitor | | (G) Others | | | | modifier | Content | of Cl⁻ | | |
| | | Content | | Content | | Content | Content | of Na⁺ | content | Evaluation | |
| | | (% by | | (% by | | (% by | (% by | (ppm by | (ppm by | Dielectric | Migration |
| | Type | mass) | Type | mass) | Type | mass) | mass) | mass | mass) | characteristics | resistance |
| Example 154 | — | — | MIR-500-60T | 15% | — | — | 1.0% | 6 | 6 | A | A |
| Example 155 | — | — | MIR-500-60T | 15% | — | — | 1.0% | 6 | 6 | A | A |
| Example 156 | — | — | MIR-500-60T | 15% | — | — | 1.0% | 6 | 6 | A | A |
| Example 157 | — | — | MIR-500-60T | 15% | — | — | 1.0% | 6 | 6 | A | B |
| Example 158 | — | — | MIR-500-60T | 15% | — | — | 1.0% | 6 | 6 | A | A |
| Example 159 | — | — | MIR-500-60T | 15% | — | — | 1.0% | 6 | 6 | A | A |
| Example 160 | — | — | MIR-500-60T | 15% | — | — | 1.0% | 6 | 6 | A | A |
| Example 161 | — | — | MIR-500-60T | 15% | — | — | 1.0% | 6 | 6 | A | B |
| Example 162 | — | — | MIR-500-60T | 15% | — | — | 1.0% | 6 | 6 | A | A |
| Example 163 | — | — | MIR-500-60T | 15% | — | — | 1.0% | 6 | 6 | A | A |
| Example 164 | — | — | MIR-500-60T | 15% | — | — | 1.0% | 6 | 6 | A | A |
| Example 165 | — | — | MIR-500-60T | 15% | — | — | 1.0% | 6 | 6 | A | A |
| Example 166 | — | — | MIR-500-60T | 15% | — | — | 1.0% | 6 | 6 | A | A |
| Example 167 | — | — | MIR-500-60T | 15% | — | — | 1.0% | 6 | 6 | A | A |
| Comparative | — | — | — | — | — | — | 0.0% | 5 | 5 | B | D |
| Example 1 | | | | | | | | | | | |
| Comparative | — | — | — | — | — | — | 6.0% | 100 | 100 | C | E |
| Example 2 | | | | | | | | | | | |
| Comparative | — | — | — | — | — | — | 0.0% | 50 | 50 | C | D |
| Example 3 | | | | | | | | | | | |
| Comparative | — | — | — | — | — | — | 3.0% | 30 | 30 | C | D |
| Example 4 | | | | | | | | | | | |

From the evaluation results shown in the tables, it was found that the composition according to the embodiment of the present invention had excellent dielectric characteristics and excellent migration resistance.

It was found that, in a case where the average particle diameter of the filler X was 150 nm or less, the migration resistance was more excellent (Examples 1 to 13 and the like).

In addition, it was found that, in a case where the content of the surface modifier was 2.5% by mass or less with respect to the total mass of the filler X, both of the dielectric characteristics and the migration resistance were more excellent (Examples 1 to 14 and the like). In addition, from the same comparison, it was found that both of the dielectric characteristics and the migration resistance were more excellent, when containing the sodium ion, in a case where the content of the sodium ion was 20 ppm by mass or less with respect to the total solid content of the composition, or when containing the chloride ion, in a case where the content of the chloride ion was 20 ppm by mass or less with respect to the total solid content of the composition.

In each of Examples, instead of forming the composition layer using the composition, the composition layer was formed on the base material using a transfer film produced by the following procedure, and the same evaluations as those of the composition was performed, and the same evaluation results as those of the composition were obtained.

The obtained composition was applied onto a temporary support (PET film, LUMIRROR 16FB40, thickness: 16 μm, manufactured by Toray Industries, Inc.), and dried to form a composition layer having a thickness of 10.0 μm.

Next, a cover film (polypropylene film, FG-201, thickness: 30 μm, manufactured by Oji F-Tex Co., Ltd.) was provided on the composition layer to obtain a transfer film.

The cover film was peeled off from the transfer film obtained above, and the exposed composition layer was laminated on a base material in various evaluations to form a composition layer. The lamination was performed under the following conditions using a vacuum laminator (manufactured by MCK Co., Ltd.): a substrate temperature of 40° C., a rubber roller temperature of 100° C., a linear pressure of 3 N/cm, and a transportation speed of 2 m/min. Next, the temporary support was peeled off from the obtained sample. Thereafter, in a case where various evaluations were carried out by the same procedures as those for the composition described above, the same results were obtained.

The transfer film of each example was laminated on both surfaces of a glass epoxy base material (CCL-EL190T, thickness: 1.0 mm, manufactured by MITSUBISHI GAS CHEMICAL COMPANY, INC.) on which a circuit pattern had been formed, thereby forming a composition layer on both surfaces of the glass epoxy base material. At this time, a vacuum laminator was used. The lamination was performed under the following conditions using a vacuum laminator manufactured by MCK Co., Ltd.: a substrate temperature of 40° C., a rubber roller temperature of 100° C., a linear pressure of 3 N/cm, and a transportation speed of 2 m/min.

A pattern having a via with a diameter of q60 μm at a predetermined position was formed on the composition layer, a heating treatment was performed, the residue was removed with a sodium permanganate aqueous solution as a roughening liquid, and an electroless plating treatment was performed. Next, a resist pattern was formed at a predetermined position using a known dry film resist, and an electrolytic plating treatment was performed. Next, the resist pattern was peeled off with a stripper.

Finally, a seed layer etching treatment was performed, and then a heating treatment (200° C., 1 hour) was performed to form a copper wire on the cured film.

The above-described process from the lamination to the heating treatment was performed three times, and finally, a solder resist was formed as an outermost layer, and a semiconductor element was further sealed and mounted to produce a semiconductor package. The obtained semiconductor package was mounted at a predetermined position of a printed wiring board to obtain a semiconductor package substrate. It was found that the obtained semiconductor package substrate normally operated.

### EXPLANATION OF REFERENCES

12: temporary support
14: composition layer
16: cover film
100: transfer film

What is claimed is:

1. A composition comprising:
a resin; and
a filler X surface-modified with a surface modifier,
wherein a content of the filler X is 50.0% by mass or more with respect to a total solid content of the composition,
an average particle diameter of the filler X is 300 nm or less, and
a content of the surface modifier is 3.0% by mass or less with respect to a total mass of the filler X.

2. The composition according to claim 1,
wherein the filler X includes at least one selected from the group consisting of silicon dioxide, boron nitride, barium sulfate, and silicate.

3. The composition according to claim 1,
wherein the average particle diameter of the filler X is 150 nm or less.

4. The composition according to claim 1,
wherein the content of the filler X is 90.0% by mass or less with respect to the total solid content of the composition.

5. The composition according to claim 1,
wherein the content of the surface modifier is 2.5% by mass or less with respect to the total mass of the filler X.

6. The composition according to claim 1,
wherein the content of the filler X is 60.0% by mass or more with respect to the total solid content of the composition,
the average particle diameter of the filler X is 150 nm or less, and
the content of the surface modifier is 2.0% by mass or less with respect to the total mass of the filler X.

7. The composition according to claim 6,
wherein the content of the surface modifier is 0.5% by mass or more and 1.5% by mass or less with respect to the total mass of the filler X.

8. The composition according to claim 6,
wherein the content of the filler X is 70.0% by mass or more with respect to the total solid content of the composition.

9. The composition according to claim 1,
wherein the resin includes at least one selected from the group consisting of a phenol resin, an epoxy resin, a polyphenylene ether resin, a silicone resin, a benzocyclobutene resin, a fluorene resin, an acrylic resin, a methacrylic resin, a liquid crystal polymer, a polyethersulfone, a polyarylate, a polyether imide, a polybenzimidazole, a polyphenylsulfone, a polycarbonate, an acrylonitrile-butadiene-styrene resin, and a polyphenylene sulfide.

10. The composition according to claim 1,
wherein the resin includes at least one selected from the group consisting of a phenol resin and an epoxy resin.

11. The composition according to claim 1,
wherein the composition contains no sodium ion, or
in a case of containing a sodium ion, a content of the sodium ion is 50 ppm by mass or less with respect to the total solid content of the composition.

12. The composition according to claim 1,
wherein the composition contains no chloride ion, or
in a case of containing a chloride ion, a content of the chloride ion is 50 ppm by mass or less with respect to the total solid content of the composition.

13. The composition according to claim 1,
wherein the composition satisfies at least one of containing the resin having an ethylenically unsaturated group or further containing a polymerizable compound having an ethylenically unsaturated group.

14. The composition according to claim 10, further comprising:
a photopolymerization initiator.

15. A transfer film comprising:
a temporary support; and
a composition layer formed of the composition according to claim 1.

16. A method for manufacturing a laminate, comprising:
a step of forming a composition layer on a base material using the composition according to claim 1;
a step of forming a pattern having a via on the composition layer; and
a step of heating or exposing the pattern.

17. A laminate manufactured by the method for manufacturing a laminate according to claim 16.

18. A cured film obtained by curing the composition according to claim 10.

19. The composition according to claim 2,
wherein the average particle diameter of the filler X is 150 nm or less.

20. The composition according to claim 2,
wherein the content of the filler X is 90.0% by mass or less with respect to the total solid content of the composition.
